(19) United States
(12) Patent Application Publication
(10) Pub. No.: US 2004/0217382 A1
(43) Pub. Date: Nov. 4, 2004

(54) Electron emission film and electric field electron emission device

(76) Inventor: Kazuo Konuma, Tokyo (JP)

Correspondence Address: YOUNG & THOMPSON, 745 SOUTH 23RD STREET 2ND FLOOR, ARLINGTON, VA, 22202

(21) Appl. No.: 10/479,790

(22) PCT Filed: Jul. 31, 2002
(86) PCT No.: PCT/JP02/07801

(30) Foreign Application Priority Data
Aug. 1, 2001 (JP) 2001-233873

(51) Int. Cl. H01L 27/10

(52) U.S. Cl. 257/202

(57) ABSTRACT

An electron emission film capable of enhancing or suppressing electron emitting characteristics at part of an electron emitting surface, and an electric field electron emission device. Many single-wall carbon nanotubes each having a slender crystal structure are arranged at the center of a CNT film (13) in such a posture as to project almost vertically with respect to the film surface. That is, a fiber structure at a specific surface (raised surface (14)) is oriented vertically to promote electron emission, or a fiber structure is made flat by an action of surface tension to suppress electron emission from a specific surface. For example, the edge portion of a CNT film, which is an area from which electrons are emitted curvedly, is rendered a flat-hair surface (15).

### TECHNICAL FIELD

The present invention relates to an electron emission film serving as an electron source, and an electric field electron emission device provided with the electron emission film.

### BACKGROUND ART

There has been proposed a variety of electric field electron emission devices using an electron emission film. Examples of electron emission films include a diamond film, a DLC (Diamond Like Carbon) film, a carbon film photoresist coated by a calcined organic film, and a carbon nanotube (CNT) film. The CNT film is a material discovered by Iijima in 1991 (for details refer to “Nature”, Vol. 354, pp. 56-58, 1991). In the following, a description will be made in detail of the CNT film.

The CNT is a fibrous crystal on the nano scale to the submicron scale in diameter, including as constituents carbon atoms. Their length ranges from the micron scale to the millimeter scale. There have been reported a single layer carbon nanotube having a hollow structure, which consists of a single layer cylinder of rolled graphene sheet, and a multilayer carbon nanotube consisting of many layers of graphene sheets. Additionally, the CNT whose hollow cylinder is filled with various materials has also been introduced. There is found in Japanese Patent Application laid open No. 2000-327317 an example of a method for manufacturing the CNT with its cylindrical axis being filled up.

Moreover, there is a carbon nanotube having a structure in which a graphite sheet overlaps a fibrous axis at right angles. Further, so-called nanocoil has a structure in which a fibrous axis is winded and formed into a coil.

As described above, in addition to the narrow sense of carbon nanotubes (single layer or multilayer), others having similar structures have been reported. In this specification, they are all referred to as carbon nanotube. Besides, nanotubes being similar in structure to the carbon nanotube but different in constituent element from it have also been reported. For example, there have been reports on a boron nitride (BN) nanotube and a silicon nanotube. These nanotubes are different in element, but possess in common a characteristic of having fibrous forms and pointed tips, and, therefore, hereinafter referred to as carbon nanotube or CNT in the wide sense, including those that are different in constituent element.

Here, the CNT film means an object having a plurality of fibriform CNTs so as to form a film. Incidentally, in one case, only the CNTs form almost a film in aggregates, in the other, however, binders are included in the CNTs to form a film. As to the CNT film-forming, there is disclosed a technique using a binder called “vehicle” in Japanese Patent Application laid open No. 2001-43602. The vehicle contains 99% of isoamyl acetate and 1% of cellulose nitrate.

There is disclosed an example of the most simple configuration of an electric field electron emission device in Japanese Patent Application laid open No. 2001-143645. This patent application describes the configurations of a cathode panel and a fluorescent material that emits light when irradiated by electrons emitted from the cathode panel. FIG. 1 is a diagram showing the typical configuration of the cathode panel. The cathode panel 1000 depicted in FIG. 1 comprises a glass substrate 1001, a metal wiring 1003 formed on one surface of the glass substrate 1001, and a CNT film 1004 as an electron emission film firmly fixed on the metal wiring 1003.

Japanese Patent Application laid open No. 2001-130904 discloses a method for firmly fixing the CNT film on a substrate. Other than this, a variety of electron emission film adhering methods have been proposed. For example, there has been disclosed a method for adhering the CNT film to a base metal film by annealing treatment in a vacuum after splay coating. Japanese Patent Application laid open No. 2001-110303 discloses a technique for electrodepositing the CNT in the form of a film. In addition, Japanese Patent Application laid open No. 2000-353467 discloses a method for selectively adhering an electron emission film to a substrate.

There have been proposed various types of methods for changing the surface character of the CNT film. For example, there is disclosed a method for applying a metal coating to make up for the surface conductivity of the CNT film in Japanese Patent Application laid open No. 2001-096499. On the other hand, there is found a method for changing the surface character so that the surface can emit electrons easily in Japanese Patent Application laid open No. 2001-035360. According to the method, a sheet of paper is put on the surface of the CNT film, and after combining the paper and the CNT film, the paper is stripped off together with part of the CNT film to expose fiber structure inside the CNT film.

Japanese Patent Application laid open No. 2001-141056 introduces an alignment method (a method of orientation) by casting or molding. Japanese Patent Application laid open No. 2001-118488 discloses an insulating film for preventing electron emission from the edge of an emitter film.

Besides, there has been disclosed techniques concerning an electric field electron emission device using an electron emission film in Japanese Patent Application laid open No. 2000-340098, Japanese Patent Application laid open No. 2000-243218 and Japanese Patent Application laid open No. 2001-143602. The techniques described in the above-mentioned three patent applications are related to a structure called normal gate type.

In the normal gate type structure, a gate electrode is placed above an electron emission film for applying electric field so as to allow electrons to escape from the electron emission film upon the principle of field emission. An insulating layer is placed between the gate electrode and the electron emission film, except an electron emitter region (emitter hole). In the emitter hole, the gate electrode and the insulating layer are removed, and the surface of the electron emission film is exposed to a vacuum. Incidentally, there have also been proposed an electric field electron emission device using an electron emission film having a structure called suspend gate type and that having a structure called under gate type, in addition to the aforementioned normal gate type one.

FIG. 2 is a diagram showing an example of a conventional suspend gate type cathode panel. The cathode panel depicted in FIG. 2 comprises a CNT film 1014 having a raised surface (raised-hair surface) 1015, and grid electrodes 1016 arranged thereon. That is, the CNT film 1014 is provided with the “raised surface” according to the method disclosed in the above-mentioned Patent Application laid open No. 2001-035360 and the alignment method (orientating method) by casting or molding described in Patent Application laid open No. 2001-141056, and on the CNT film 1014, the grid electrodes 1016 are disposed.

The surface of the CNT film, which is referred to as “raised surface” in this specification, is in the condition where many slender carbon nanotubes are arranged in such a posture as to protrude in a direction substantially perpendicular to the film surface. This condition is associated with raised or standing hairs. In other documents, the “raised surface” may be referred to as “alignment” or “orientation”. Strictly, the raised surface differs from the alignment and orientation. However, they indicate about the same conditions.

FIG. 3 is a diagram showing an example of the configuration of an under gate type cathode panel. The cathode panel having the structure illustrated in FIG. 3 is characterized in that an under gate 1027 for controlling electron emission is arranged below a CNT film 1024.

Problems that the Invention is to Solve

The aforementioned electron emission devices using the electron emission film as an electron source, however, has problems in that the electrons emitted from the edge of the CNT film used as electron emission film are extraordinarily large in quantity as compared to those from the flat surface of the CNT film (at least, more than twice the amount), and if the path of emitted electrons is curved, the screen resolution of a field emission display (FED) may be deteriorated.

Moreover, since electron emitting characteristics at the edge portion depend heavily on the shape of the edge portion, there are great fluctuations in stability of electron emission, reproducibility and pixels (each CNT film).

As just described, in the surface of the electron emission film, it may be occasionally necessary to suppress electron emission from a part of the surface. However, according to the above-mentioned prior art technologies, it is impossible to improve electron emitting characteristics at a part of the electron emitting surface or suppress electron emission therefrom.

In the above Patent Application laid open No. 2001-118488, a description is given of an insulating film for preventing electron emission from the edge of an emitter film. This technique, however, makes just a simple device for the form of a gate insulating film. Namely,the technique described in the patent application does not suggests or indicates any device for dividing an electron emitting surface exposed at the bottom of the emitter hole (exposed surface of a DLC film, etc.) into parts to thereby control electron emitting characteristics with respect to each of the parts.

After all, with the prior art technologies, an electron emitting surface is not divided into parts so as to vary electron emitting characteristics at the surface according to the parts. Consequently, it is required to cut out a minimum area that needs the control of electron emitting characteristics or to apply an insulating film coating, etc. in order to produce a micropattern. The aforementioned problem with the edge portion is particularly acute when defining a micropattern on the electron emission film. In addition, there is another problem of causing insufficiency of adhesion between a substrate and a film.

It is therefore an object of the present invention to provide an electron emission film for improving electron emitting characteristics at part of an electron emitting surface or suppress electron emission therefrom, and an electric field electron emission device provided with the electron emission film.

It is another object of the present invention to provide an electric field electron emission device in which ineffective electrons are not generated and an abnormal discharge hardly occurs.

### DISCLOSURE OF THE INVENTION

In accordance with the present invention, to achieve the above object, there is provided a continuous electron emission film, which serves as an electron source and includes at least two areas, wherein an electric field necessary for the emission of a certain amount of electrons on the surface of one of the areas is different from that on the surface(s) of the other area(s).

In accordance with another aspect of the present invention, there is provided a continuous electron emission film, which serves as an electron source and includes at least two areas, wherein the work function of the material surface, which emits electrons, of one of the areas is different from that of the other area(s).

In accordance with yet another aspect of the present invention, there is provided a continuous electron emission film, which serves as an electron source and includes at least two areas, wherein, regarding irregularities on the surfaces of the areas, the average radius of the edges of convexities in one of the areas is different from that in the other area(s).

In accordance with yet another aspect of the present invention, there is provided a continuous electron emission film, which serves as an electron source and includes at least two areas, wherein the amount of emitted electrons per unit area in one of the areas is different from that in the other area(s).

In accordance with yet another aspect of the present invention, there is provided a continuous electron emission film, which serves as an electron source and includes at least two areas, wherein, regarding irregularities on the surfaces of the areas, the density of convexities per unit area in one of the areas is different from that in the other area(s).

In accordance with yet another aspect of the present invention, there is provided a continuous electron emission film, which serves as an electron source and includes an innermost area, an intermediate area and an outermost area, wherein the electron emission characteristics of the innermost area and outermost area is different from that of the intermediate area.

In accordance with yet a further aspect of the present invention, there is provided a continuous electron emission film provided with fiber structure, which serves as an electron source and includes at least two areas, wherein the rate at which fibers are oriented in a direction perpendicular to the film in one of the areas is different from that in the other area(s).

In accordance with yet another aspect of the present invention, there is provided a continuous electron emission film provided with fiber structure, which serves as an electron source and includes at least two areas, wherein the rate at which fibers are oriented in a direction parallel to the film in one of the areas is different from that in the other area(s).

In accordance with yet another aspect of the present invention, there is provided a continuous electron emission film provided with fiber structure, which serves as an electron source and includes at least two areas, wherein the proportion of fibers, which form the fiber structure, having diameters smaller than a predetermined one varies according to the areas.

In accordance with yet another aspect of the present invention, there is provided a continuous electron emission film provided with fiber structure, which serves as an electron source and includes an innermost area, an intermediate area and an outermost area, wherein the rate at which fibers are oriented in a direction parallel to the film in the innermost and outermost areas is higher than that in the intermediate area.

In accordance with yet another aspect of the present invention, there is provided a continuous electron emission film, which serves as an electron source and includes at least two areas, wherein, in one of the areas, an electric field necessary for emitting electrons is large, the work function of a material surface which emits electrons is large, regarding irregularities on the surface of the area, the average radius of the edges of convexities is large, the density of convexities per unit area is low, and/or the amount of emitted electrons per unit area is small as compared to the adjacent area(s).

In accordance with yet another aspect of the present invention, there is provided a continuous electron emission film, which serves as an electron source and includes at least two areas, wherein one of the areas is located in at least part of the periphery of the electron emission film, and in the area, an electric field necessary for emitting electrons is large, the work function of a material surface which emits electrons is large, regarding irregularities on the surface of the area, the average radius of the edges of convexities is large, the density of convexities per unit area is low, and/or the amount of emitted electrons per unit area is small as compared to the adjacent area(s).

In accordance with yet another aspect of the present invention, there is provided a continuous electron emission film, which serves as an electron source and includes at least two areas, wherein one of the areas is located in at least part of the central portion of the electron emission film or located so as not to include the periphery of the film, and in the area, an electric field necessary for emitting electrons is large, the work function of a material surface which emits electrons is large, regarding irregularities on the surface of the area, the average radius of the edges of convexities is large, the density of convexities per unit area is low, and/or the amount of emitted electrons per unit area is small as compared to the adjacent area(s).

In accordance with yet another aspect of the present invention, there is provided a continuous electron emission film, which serves as an electron source and includes at least three areas, wherein one of the areas is located in at least part of the periphery of the electron emission film or at least part of the central portion thereof so as not to include the periphery of the film, and in the area, an electric field necessary for emitting electrons is large, the work function of a material surface which emits electrons is large, regarding irregularities on the surface of the area, the average radius of the edges of convexities is large, the density of convexities per unit area is low, and/or the amount of emitted electrons per unit area is small as compared to the adjacent area(s).

In accordance with yet a further aspect of the present invention, there is provided an electric field electron emission device provided with one of the electron emission films described above, wherein the electron emission film is arranged so that part of the surface of the prescribed area or the side of the film is contacted with an insulating film.

In accordance with yet a further aspect of the present invention, there is provided an electric field electron emission device provided with one of the electron emission films described above, wherein the electron emission film is arranged so that part of the surface or the side of the first area including part of the periphery of the film,the second area not including part of the central portion or the periphery of the film or the third area including part of the periphery of the film and not including part of the central portion or the periphery of the film is contacted with an insulating film.

Preferably, the side or edge part of the electron emission film of the electric field electron emission device is covered by a conductive film. Besides, a gate electrode is preferably disposed on part of the upper surface of the insulating film.

Further, it is desirable that the edge of the gate electrode corresponding to a hole made therein be tapered in an upward direction or sloped upwardly.

### BRIEF DESCRIPTION OF THE DRAWINGS

FIG. 1 is a diagram showing the typical configuration of a conventional cathode panel.

FIG. 2 is a diagram showing an example of a conventional suspend gate type cathode panel.

FIG. 3 is a diagram showing an example of the configuration of an under gate type cathode panel.

FIG. 4 is a side view of a cathode panel of a cold cathode according to the first embodiment of the present invention.

FIG. 5 is a front view of a cathode panel of a cold cathode according to the first embodiment of the present invention.

FIG. 6 is a view showing a frame format of the surface of a CNT film in a raised (raised-hair) surface condition.

FIG. 7 is a view showing a frame format of the flat (flat-hair) surface of a CNT film.

FIG. 8 is a cross sectional view, taken along the broken line A-A′ of FIG. 5, of an FED using a cathode panel according to the first embodiment of the present invention.

FIG. 9 is a cross sectional view, taken along the broken line B-B′ of FIG. 5, of an FED using a cathode panel according to the first embodiment of the present invention.

FIG. 10 is a side view of a cathode panel according to the second embodiment of the present invention.

FIG. 11 is a side view of a cathode panel according to the third embodiment of the present invention.

FIG. 12 is a side view of a cathode panel (normal gate structure) according to the fourth embodiment of the present invention.

FIG. 13 is a side view of a cathode panel according to the fifth embodiment of the present invention.

FIG. 14 is a side view of a cathode panel according to the eighth embodiment of the present invention.

FIG. 15 is a side view of a cathode panel according to the ninth embodiment of the present invention.

FIG. 16 is a side view of a cathode panel according to the tenth embodiment of the present invention.

FIG. 17 is a cross sectional view of an emitter hole of a carbon nanotube FED.

FIG. 18 is an enlarged view of the bottom of an emitter hole of a cathode panel.

FIG. 19 is a cross sectional view of an FED using carbon nanotubes according to the twelfth embodiment of the present invention.

FIG. 20 shows diagrams illustrating the process of manufacturing a cathode panel according to the twelfth embodiment of the present invention.

FIG. 21 is a cross sectional view showing the configuration of an FED according to the thirteenth embodiment of the present invention.

FIG. 22 is a diagram showing a stripe pattern of a surrounding cover.

FIG. 23 shows diagrams illustrating the process of forming a cathode panel of an FED according to the thirteenth embodiment of the present invention.

FIG. 24 is a graph showing the emission characteristics of each electron beam in an FED according to the thirteenth embodiment of the present invention.

FIG. 25 is a graph showing the sums of electron emissions.

FIG. 26 shows diagrams illustrating a variety of shapes of the electron emitting surface according to the fourteenth embodiment of the present invention.

FIG. 27 is a side view of an FED according to the fifteenth embodiment of the present invention.

FIG. 28 is a graph showing another design index of an electron emitting surface according to the fifteenth embodiment of the present invention.

FIG. 29 is a side view showing the configuration of an FED according to the sixteenth embodiment of the present invention.

FIG. 30 is a side view showing the configuration of an FED according to the seventeenth embodiment of the present invention.

FIG. 31 is a diagram illustrating the drive of an FED with respect to pixels according to the eighteenth embodiment of the present invention.

FIG. 32 is a graph illustrating pulse-width modulation (PWM) for driving an FED.

FIG. 33 shows diagrams illustrating appearances of emitter holes.

FIGS. 34 is a graph showing the emission characteristics.

Incidentally, the reference numerals 10, 25, 30, 35, 40, 45, 47 and 49 designate cathode panels. The reference numeral 11 designates a glass substrate. The reference numeral 12 designates a metal wiring. The reference numerals 13 and 51 designate CNT films. The reference numeral 14 designates a raised (raised-hair) surface portion. The reference numeral 15 designates a flat (flat-hair) surface portion. The reference numeral 16 designates an external drawer pad. The reference numeral 17 designates a CNT film base part. The reference numeral 21 designates a fluorescent material. The reference numeral 22 designates a power supply. The reference numeral 23 designates an ampere meter. The reference numerals 26, 28, 34 and 38 designate conductive covers. The reference numerals 27, 67 and 86 designate emitter holes. The reference numeral 31 designates a gate wiring. The reference numeral 32 designates a gate insulating film. The reference numeral 33 designates a grid electrode. The reference numeral 36 designates an under gate. The reference numeral 41 designates an insulating film. The reference numeral 42 designates a gate wiring. The reference numerals 50 and 60 designate FEDs. The reference numerals 52, 68 and 82 designate insulating films. The reference numerals 53, 65, 83 and 83a designate gate electrodes. The reference numerals 55 and 84 designate optical screens. The reference numeral 56 designates a cathode wiring. The reference numeral 57a designates a centermost area. The reference numeral 57b designates an intermediate area. The reference numeral 57c designates an outermost area. The reference numeral 61 designates a graphite emission film. The reference numeral 63 designates an aluminum center cover. The reference numeral 64 designates a silver paste surrounding cover. The reference numeral 85 designates a target area. The reference numeral 91 designates a CNT paste block.

### BEST MODE FOR CARRYING OUT THE INVENTION

In the following, a description of preferred embodiments of the present invention will be given in detail. Here, electron emission films according to the embodiments of the present invention will be described with respect to each characteristic.

[Electron Emission Film with the First Characteristic]

First, an electron emission film with the first characteristic will be described. Here, the first characteristic is that, in a continuous electron emission film including at least two areas, an electric field necessary for the emission of a certain amount of electrons on the surface of one of the areas is different from that on the surface(s) of the other area(s). When an electron emission film has such characteristic, on the surface of its one area, a work function is increased, pointed edges where electric fields are focused are reduced or removed and/or the density of pointed edges per unit area is decreased so that electrons are not emitted in a low electric field.

With this construction, it is possible to realize an electric field electron emission device provided with an electron emission film having an electron emitting surface where electrons are emitted with a higher electric field in one area as compared to area(s) other than the one area. In order to obtain the surface where a work function is large, surface modifications, such as the deposition of a very thin film made of a material with a large work function, is made on the surface. Additionally, for example, the work function can be increased by oxidizing or nitriding the surface in an oxygen or nitrogen gas environment.

On that occasion, only the specific surface is irradiated by laser light or an electron beam to thereby selectively make the surface react. Besides, for example, the surface that has undergone ion implantation can be modified to have a large work function. In some cases, heat treatment is carried out after ion irradiation to repair damage caused by the irradiation, while in other cases, the damage is left intentionally.

In order to reduce the pointed edges, there are some methods such as surface polishing and chemical etching. The surface can also be flattened by ion milling. By adjusting the energy of ions, the surface can be flattened with a high degree of accuracy. For a very rough film, irregularities are reduced, for example, by irradiating the surface of the film with heavy ions with high energy, and after the irregularities have been reduced, the surface is irradiated by light ions with low energy. Thus, the fine structure of the surface is evened out.

In the case where an electron emission film is characterized in that a part of its surface emits electrons in a lower electric field as compared to the surface other than the part, on the part of the surface of the electron emission film, a work function is reduced, pointed edges where electric fields are focused are increased and/or the pointed edges are further sharpened so that electrons are not emitted in a low electric field.

With this construction, it is possible to realize an electric field electron emission device provided with an electron emission film having an electron emitting surface in which electrons are emitted with a higher electric field in one area as compared to area(s) other than the one area. In order to obtain the surface where a work function is small, surface modifications, such as the deposition of a very thin film made of a material with a small work function, is made on the surface. Additionally, for example, the work function can also be lessened by oxidizing or nitriding the surface in an oxygen or nitrogen gas environment on the different condition than that in the aforementioned case.

On that occasion, only the specific surface is irradiated by laser light or an electron beam to thereby selectively make the surface react. Besides, for example, the surface that has undergone ion implantation on the different condition than that in the aforementioned case can be modified to have a small work function. In some cases, heat treatment is carried out after ion irradiation to repair damage caused by the irradiation, while in other cases, the damage is left intentionally.

Whether the work function is increased or decreased depends on whether the work function of a surface to be added later is relatively large or small compared to the work function originally provided to the surface. The work function is measured with respect to each of various materials, and data on them are sorted out. Herewith, a new surface is added to the surface so as to answer the purpose.

When damage (defects, etc.) is left, the work functions of some films become large, while those of other films become small. To a film whose tendency is obvious in the first place, treatment is given based on the tendency to thereby achieve a desired work function. Meanwhile, when the tendency of a film is unapparent, a preliminary experiment is performed on the result of having inflicted damage to the film. After the tendency of its change has been figured out, the film is actually used for an electric field electron emission device, and a desired work function can be obtained.

On the other hand, the pointed edges can be increased by means of a chemical etch technique. For an electron emission film formed of various materials in combination, etchant is selected so as to partly etch away the film. Thus, irregularities are produced. In addition, the surface can be roughened by ion milling. By adjusting the energy of ions, the surface can be made rough.

For example, when the surface of an electron emission film is irradiated by heavy ions with a low irradiation density and high energy, only the part irradiated by the heavy ions is dug deep, and materials for the film dug out by the ion irradiation adhere again to the vicinity of the part, which raises the surface of the film. Thus, irregularities are produced on the surface of the film. The ion irradiation technique may be used in combination with the chemical etching. When irradiating an electron emission film with ions in advance to produce defects in parts and conducting the chemical etching after that, etch process in the defective parts is promoted, which creates etch pits.

[Electron Emission Film with the Second Characteristic]

The second characteristic is that, in a continuous electron emission film including at least two areas, the work function of the material surface, which emits electrons, of one of the areas is different from that of the other area(s). In this case, in order to, for example, lessen the work function, cesium is deposited on the surface. On the surface whose work function becomes smaller (or larger), changes can be observed not only in electron emitting characteristics but also in the photoelectric characteristics.

[Electron Emission Film with the Third Characteristic]

The third characteristic is that, in a continuous electron emission film including at least two areas, regarding irregularities on the surfaces of the areas, the average radius of the edges of convexities in one of the areas is different from that in the other area(s). When an electron emission film has such characteristic, the average edge radius of convexities in each area can be found by, for example, observing a certain area with a SEM (scanning electron microscope), and measuring the edge radii of plural convexities observed in the field of view.

Thus, an average edge radius is obtained, and the obtained radius is compared area by area with others. When there is more than double of a difference between the average edge radius in one area and that in the other area(s), significant differences are made among the electron emitting characteristics of the respective areas. If standard deviation (fluctuation) in the edge radii measured as above is little, even when a difference between the average edge radius in one area and that in the other area(s) is less than double, significant differences are made among the electron emitting characteristics of the respective areas. When there is more of a difference between the average edge radius in one area and that in the other area(s) than standard deviation, significant differences can be observed.

[Electron Emission Film with the Fourth Characteristic]

The fourth characteristic is that, in a continuous electron emission film including at least two areas, the amount of emitted electrons per unit area in one of the areas is different from that in the other area(s). When an electron emission film has such characteristic, on the surface of its one area, a work function is increased, pointed edges where electric fields are focused are reduced, the density of pointed edges per unit area is decreased, and/or conductivity in the vicinity of the surface is decreased to limit an electron supply to the surface so that the amount of emitted electrons in part of the surface of the film becomes larger than that in the surface other than the part.

Alternatively, on the surface of one area, a work function is reduced, pointed edges where electric fields are focused are increased or further sharpened, the density of pointed edges per unit area is increased, and/or conductivity in the vicinity of the surface is increased to provide more electron supplies to the area as compared to the other area(s) so that the amount of emitted electrons in part of the surface of the film becomes larger than that in the surface other than the part.

[Electron Emission Film with the Fifth Characteristic]

The fifth characteristic is that, in a continuous electron emission film including at least two areas, regarding irregularities on the surfaces of the areas, the density of convexities per unit area in one of the areas is different from that in the other area(s).

When the density of convexities per unit area in part of the surface of an electron emission film is higher than that in the surface other than the part, irregularities are produced by applying physical energy, such as sandblast, air blow, contact with a sheet, etc., to only the part of the film surface to roughen it. In addition, irregularities can be produced by depositing materials on the surface unevenly, or using a chemical etch technique. In the case where the film has a fibrous internal structure, the edge portions of fibers are exposed to thereby produce irregularities.

On the other hand, when the density of convexities per unit area in part of the surface of an electron emission film is lower than that in the surface other than the part, a liquid is applied on the surface so as to create a movable coat covering the fine structure of the surface by the effect of surface tension. Besides, the surface can be flattened by applying physical energy, such as surface polishing, etc., or edges may be removed by a chemical etch technique. Irregularities on the surface can also be evened out by depositing materials on the surface using a sputter deposition technique or the like.

[Electron Emission Film with the Sixth Characteristic]

The sixth characteristic is that, in a continuous electron emission film provided with fiber structure including at least two areas, the rate at which fibers are oriented in a direction perpendicular to the film in one of the areas is different from that in the other area(s).

When an electron emission film has such characteristic, the fiber structure is oriented vertically or horizontally by adhesive tape, electrostatic force, magnetic force, or the like. On the occasion of applying a magnetic field or an electric field, an electron emission device is placed in the air, in a vacuum or in solution. In the case where an electron emission device is placed in solution, the solution is solidified after applying a magnetic field or an electric field, and then the solidified solution is removed, or an electron emission film is made extremely hydrophilic to prevent the fiber structure oriented vertically from being flattened by surface tension. When the film has a fibrous internal structure, the edge portions of fibers are exposed to thereby orient the fiber structure vertically.

[Electron Emission Film with the Seventh Characteristic]

The seventh characteristic is that, in a continuous electron emission film provided with fiber structure including at least two areas, the rate at which fibers are oriented in a direction parallel to the film in one of the areas is different from that in the other area(s).

When an electron emission film has the seventh characteristic, the fiber structure is oriented in a parallel direction with the standard surface of the film. For example, part of the fiber structure is wetted with moisture so as to be oriented horizontally by the effect of surface tension. Ethanol may be sprayed on only the area where the fiber structure is to be oriented horizontally. As another method, a gel substance may be applied to only the part by screen printing and then solidified while the fiber structure is flattened out under its weight.

In some cases, the aforementioned gel substance is vaporized by a firing process to be removed after the fiber structure is oriented horizon tally. Besides, another approach to orienting the fiber structure horizontally involves the use of a roller or a squeegee to physically press the fiber structure against the surface. In this case, at the moment of losing contact with a roller, etc., that is, when a roller is moved away from the surface, the fiber structure is sometimes pulled up together with the roller, and assumes a raised-hair surface condition by contrast.

This can be prevented in the following manner. The surface of a roller, etc. is smoothed so that the fiber structure does not adhere to it. The surface of a roller, etc. and the fiber structure (e.g. carbon nanotubes) are charged with electricity or magnetized so that they are repelled by each other. The fiber structure, which adheres on a roller, etc. and is about to be raised, is pulled off the roller, or the fiber structure which adheres on a roller and assumes a raised surface condition is blown off and removed with the use of an air blow.

In addition, the fiber structure can be made in a flat-hair surface condition by pressing it against the surface of the film by surface tension of a liquid or by depositing a metal film. Here, the “flat-hair surface” condition means that the fiber structure is oriented in parallel with the film so as to cause less concentration of electric fields. Under this condition, electron emission is suppressed, and the withstand voltage of the part is improved.

When there is a pointed edge structure, it is highly likely that the part forms the origin of electric discharge. The flat-hair surface condition has an effect of hiding the origin. At the tip or edge of the fiber structure, the crystal lacks in perfectibility, and therefore a work function is small in some cases. By hiding the edge portion where a work function is small, it may be possible to suppress electron emission and improve the withstand voltage.

If the crystal lacks in perfectibility, the structure is unstable and easily broken down, thus causing a gas discharge. By hiding the edge of such structure, it may be possible to improve the withstand voltage. In the following, definition of “hide” will be explained more strictly. That is, the removal of the structure from an area with a high electric field, or in an area with a high electric field, the recovery of the structure from the condition where the structure makes the electric field even higher is expressed as “hide”.

The fiber structure can be embedded in a conductive electron emission film by placing it in a flat-hair surface condition, and, accordingly, it is possible to prevent electric fields from concentrating at its edge. In other words, the long axis of the fiber structure is oriented in a parallel direction with an equipotential surface when the fiber structure is in a flat-hair surface condition. Consequently, it is possible to weaken the effect of electric field concentration at the edge portion of the fiber structure.

[Electron Emission Film with the Eighth Characteristic]

The eighth characteristic is that, in a continuous electron emission film provided with fiber structure including at least two areas, regarding the fiber structure, the proportion of fibers having small diameters varies according to the areas. In this case, an adhesive is contacted on the surface of the fiber structure, and then removed therefrom so as to tear off part of the fiber structure. Thus, the cut surface of each fiber is sharpened.

The fibers become thinner than before at their torn parts. The fiber structure may be stretched and extended in a thinner shape. Besides, the proportion of thin fibers can be increased by removing part of the fiber structure making use of an etch technique or ion irradiation.

When fibers become thinner, the effect of electric field concentration is heightened. Additionally, in some cases, the condition of the surface of edge portion changes, which lessens a work function and improves electron emitting characteristics.

[Electron Emission Film with the Ninth Characteristic]

The ninth characteristic is that, in a continuous electron emission film provided with fiber structure including three areas: an innermost area, an intermediate area and an outermost area, the rate at which fibers are oriented in a direction parallel to the film in the innermost and outermost areas is higher than that in the intermediate area.

When an electron emission film has the ninth characteristic, in the intermediate area where the proportion of horizontally oriented fibers is small, the proportion of vertically oriented fibers is relatively large. Consequently, the amount of emitted electrons in the intermediate area is larger than those in the other areas.

In a triode structure in which a gate electrode is placed on the periphery of an electron emission film via an insulating film and a fluorescent screen is arranged in a position opposite to the film, when the electron emission film has the ninth characteristic, the proportion of horizontally oriented fibers is large in an area near the insulating film. Therefore, electron emission is suppressed in the area.

Electrons emitted from the area sometimes jump into the insulating film and charge up the film, or jump into the gate electrode and do not reach to the fluorescent screen. For this reason, electron emission from the area, which may be of no use and cause failure, is suppressed.

On the other hand, it is difficult to control the innermost area by the gate electrode. In addition, application of a high voltage of positive polarity to the fluorescent screen induces a “noncontrollable electron emission phenomenon” in which electrons are emitted from the innermost area due to the potential at the fluorescent screen regardless of the potential at the gate electrode. If fibers in the innermost area are oriented horizontally so as to cause less electron emission, the above-mentioned “noncontrollable electron emission phenomenon” can be restrained.

[Electron Emission Film with the Tenth Characteristic]

The tenth characteristic is that, in a continuous electron emission film provided with fiber structure including at least two areas, one of the areas is covered by a conductive film and the conductivity of the conductive film is larger than that of the other area(s).

When an electron emission film has such characteristic, electron emission may be encouraged since the part covered by the conductive film is hardly electrostatically charged. In the following, this will be described in detail. When electrons are emitted from a surface which is easily electrostatically charged, the emitted electrons may attach onto the surface again, and the surface may be charged in a negative potential. If the surface is charged in a negative potential, an electric field on the surface is lessened, and electron emission is suppressed.

On the other hand, if the surface is covered by a conductive film, even when there is any electron that attaches onto the surface again, the electron is carried in the conductive film and thereby removed. Thus, the surface can continue emitting electrons without being electrostatically charged.

In the case where an area is covered by a conductive film, the tendency of a change in electron emitting characteristics varies according to its shape, that is, according to whether irregularities in the area are smoothed or sharpened as compared to those before being covered. If the irregularities have been smoothed, the effect of electric field concentration is weakened, which deteriorates electron emitting characteristics. On the contrary, if the irregularities have been sharpened, the concentration of electric field is promoted, and, therefore, electron emitting characteristics are improved.

[Electron Emission Film with the Eleventh Characteristic]

The eleventh characteristic is that, in a continuous electron emission film including at least two areas, an electric field necessary for emitting electrons is large, the work function of a material surface which emits electrons is large, regarding irregularities on the surfaces of the areas, the average radius of the edges of convexities is large, the density of convexities per unit area is low and/or the amount of emitted electrons per unit area is small in one of the areas as compared to the adjacent area(s).

When an electron emission film has such characteristic, it is possible to form an area which easily emits electrons and an area which does not easily emits electrons in the electron emission film with complete control. In the case where it is difficult to define a pattern in the electron emission film itself, the electron emission film is formed to a size larger than a desired size so that one area of the film can be made emit electrons with a low electric field and the other area(s) can be prevented from emitting electrons even with a high field. By this means, the micro-fabrication of an electron emitting surface becomes possible beyond the limit of the fabrication of the electron emission film.

Incidentally, it has been observed as an accidental phenomenon that there is a case where variations exist in the electron emitting characteristics of an electron emitting surface. However, such accidental phenomenon does not reemerge, and the variations in electron emitting characteristics temporally or arbitrarily change considerably. In accordance with the present invention, a surface which easily emits electrons and a surface which does not easily emits electrons are formed intentionally with complete control. Moreover, it is possible to form areas each having a different electron emitting characteristic for the desired operation.

[Electron Emission Film with the Twelfth Characteristic]

The twelfth characteristic is that, in a continuous electron emission film including at least two areas, one of the areas is located in at least part of the periphery of the electron emission film, and in the one of the areas, an electric field necessary for emitting electrons is large, the work function of a material surface which emits electrons is large, regarding irregularities on the surface of the area, the average radius of the edges of convexities is large, the density of convexities per unit area is low and/or the amount of emitted electrons per unit area is small as compared to the adjacent area(s).

An abnormal discharge often occurs in the periphery of an electron emission film since the edge of the film has an acute-angled shape and contaminated. When an electron emission film has the aforementioned twelfth characteristic, the periphery of the film has a surface which does not easily emits electrons. Thereby, electrons can be emitted from only the central portion of the film. Besides, electron emission from the periphery is suppressed, and also an abnormal discharge hardly occurs in the periphery. Thus, it is possible to obtain an electron emission film which is less likely to discharge electricity and has a stable character.

[Electron Emission Film with the Thirteenth Characteristic]

The thirteenth characteristic is that, in a continuous electron emission film including at least two areas, one of the areas is located in at least part of the central portion of the electron emission film or located so as not to include the periphery of the film, and in the one of the areas, an electric field necessary for emitting electrons is large, the work function of a material surface which emits electrons is large, regarding irregularities on the surface of the area, the average radius of the edges of convexities is large, the density of convexities per unit area is low and/or the amount of emitted electrons per unit area is small as compared to the adjacent area(s).

When an electron emission film has the thirteenth characteristic, the central portion of the film does not easily emit electrons, and therefore, an abnormal discharge from the central portion can be suppressed. There are two cases in which an abnormal discharge occurs. In one case, when a normal gate type electric field electron emission device has a shallow emitter hole, the central portion of the film is not controllable by the gate electrode, and electrons are emitted due to the voltage at a fluorescent material. Consequently, an abnormal discharge is restrained by suppressing electron emission from the uncontrollable central portion.

In the other case, an abnormal discharge occurs due to ion irradiation. When accelerated ions enter into an electron emission film, electrons and gas are abnormally emitted from the surface of the film, which causes an arc discharge or sparks. Because of this, the performance of an electric field electron emission device is deteriorated.

In an electric field electron emission device having the normal gate structure, the bottom of an emitter hole is subject to ion irradiation at a part opposite to a fluorescent material. In particular, ions which are much larger than electrons in mass are highly likely to pour down directly onto the central portion of the bottom of the emitter hole from the fluorescent material or the periphery thereof. According to the present invention, an abnormal discharge is restrained by suppressing electron emission from the central portion of the bottom of the emitter hole, which is heavily irradiated by ions.

An electron emitted from the bottom of the emitter hole sometimes takes a path curved in some degree due to a distorted electric field at the periphery of the bottom to enter the fluorescent material. In this case, the probability that ions will fall into an electron emitting position is reduced. The specific part of an electron emission film is made into a flat-hair surface or covered by a deposited metal for the purpose of suppressing electron emission form the specific part.

[Electron Emission Film with the Fourteenth Characteristic]

The fourteenth characteristic is that, in a continuous electron emission film including at least three areas, the above-mentioned twelfth and thirteenth characteristics are united. That is, the periphery and the central portion of the film are made less likely to emit electrons, and, therefore, an abnormal discharge from the periphery and the central portion is suppressed.

[Electron Emission Film with the Fifteenth Characteristic]

The fifteenth characteristic is that, in an electric field electron emission device of the present invention, an electron emission film is arranged so that part of the surface or the side of the area described previously for at least one of the first to fourteenth characteristics is contacted with an insulating film.

When an electron emission film has the fifteenth characteristic, the surface of the electron emission film in contact with the under surface of the insulating film is flattened, or made less likely to emit electrons. Since the surface is flat, the insulating film attains a uniform thickness. Additionally, because of the fact that the surface of the electron emission film in contact with the insulating film is flat and/or less likely to emit electrons, the withstand voltage characteristic of the insulating film is improved.

Besides, when part of an electron emitting surface is flat, the surface possesses good hydrophilic or wet characteristics. Incidentally, the surface of the electron emission film in contact with the insulating film is not required to emit electrons, and may be made less likely to emit electrons.

[Electron Emission Film with the Sixteenth Characteristic]

The sixteenth characteristic is that, an electron emission film is arranged so that part of the surface or the side of the area including part of the periphery, the area not including part of the central portion or the periphery, or the area including part of the periphery and not including part of the central portion or the periphery described previously for the fourteenth characteristic is contacted with an insulating film.

When an electric field electron emission device has such characteristic, the part which is covered by the insulating film hardly emits electrons, and the surface of the part has less irregularities.

[Electron Emission Film with the Seventeenth Characteristic]

The seventeenth characteristic is that, a gate electrode is arranged on part of the upper surface of the insulating film described previously for the fifteenth and sixteenth characteristics.

When an electric field electron emission device has such characteristic, electrons are emitted due to the voltage applied to between the gate electrode and the electron emission film. Since the insulating film attains a uniform thickness and withstands a high voltage, the uniformity and reliability of electron emission is enhanced.

Referring now to the drawings, a description of preferred embodiments of the present invention will be given in detail.

[Embodiment]

The first embodiment of the present invention will be described. The cathode panel of the present invention shows an example of a cold cathode which allows only the central portion of a CNT film serving as a source of electrons to emit electrons, and prevents the periphery of the film from emitting electrons.

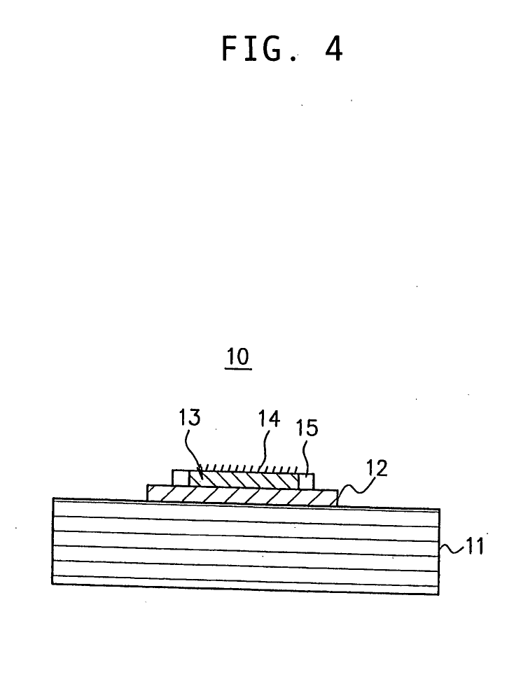

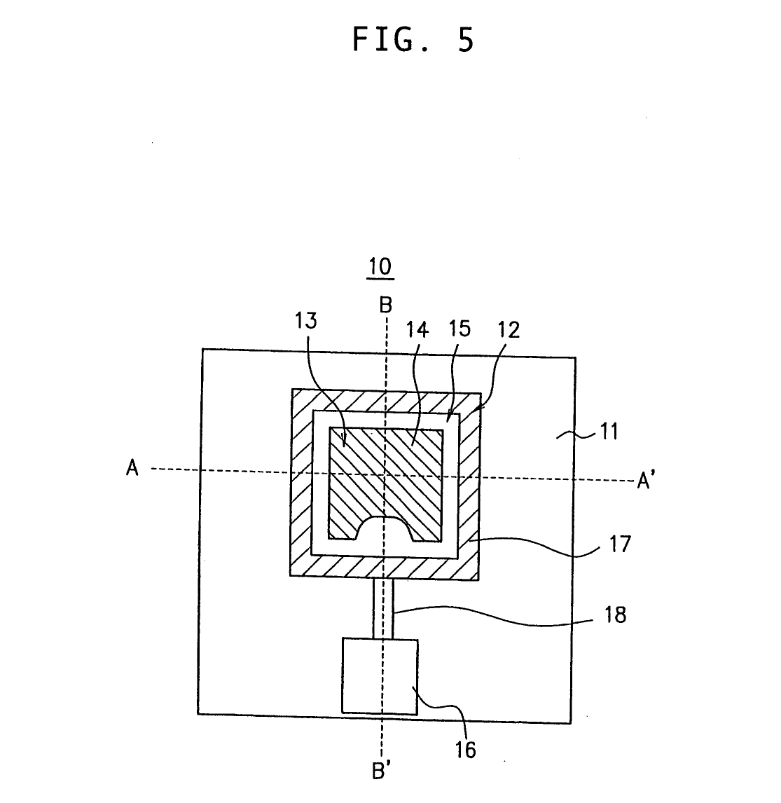

FIG. 4 is a side view of a cathode panel of a cold cathode according to the first embodiment of the present invention. FIG. 5 is a front view of the cathode panel. As shown in FIG. 4, the cathode panel 10 of the present invention comprises a glass substrate 11, a metal wiring 12 and a CNT film 13. The glass substrate 11 is 1 mm in thickness and 10 mm on a side. The metal wiring 12 is provided with an area of 200 square μm as an external drawer pad 16 as can be seen in FIG. 5, and connects the pad and a CNT film base part 17 of 500 square fi m by a wiring 18 of 50 μm in width and 200 μm in length.

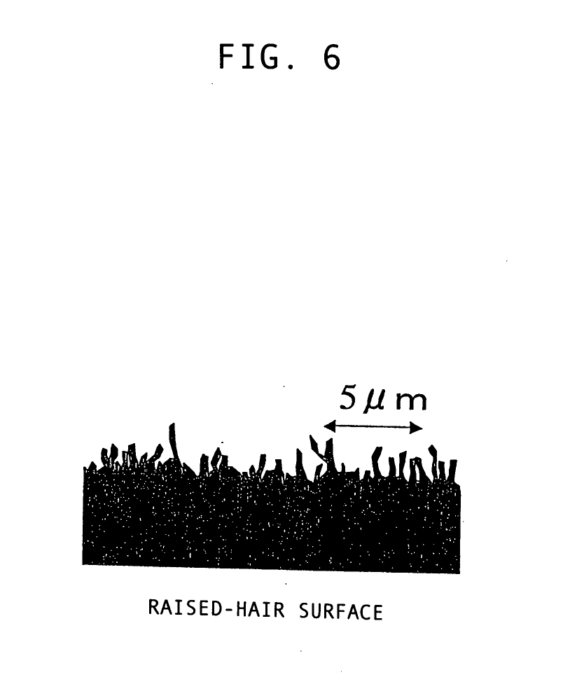

The metal wiring 12 is a gold wiring 1 μm thick, and a coating of titanium is applied in a thickness of 100 μm to the surface of the gold. The CNT film 13 is 3 μm in thickness with a size of 400 square μm. The distance between the periphery of the CNT film 13 and the periphery of the metal wiring 12 is 50 μm. The periphery and the central portion of the CNT film 13 have different characteristics. That is, in the central portion, CNT crystals are arranged so as to project vertically from the surface of the CNT film 13. FIG. 6 shows the surface in this condition.

As shown in FIG. 6, in the central portion of the CNT film, many single-wall carbon nanotubes each having a slender crystal structure are arranged in such a posture as to project almost vertically from the film surface. This condition is associated with raised or standing hairs, and, therefore, referred to as a raised surface or a raised-hair surface. In FIGS. 4 and 5, the part shown as a raised surface portion 14 (the central portion of the CNT film 13) has fine structure as shown in FIG. 6.

On the other hand, the periphery of the CNT film 13 has a flat surface portion 15, in which CNT crystals (fine structure referred to as hairs) lie flat.

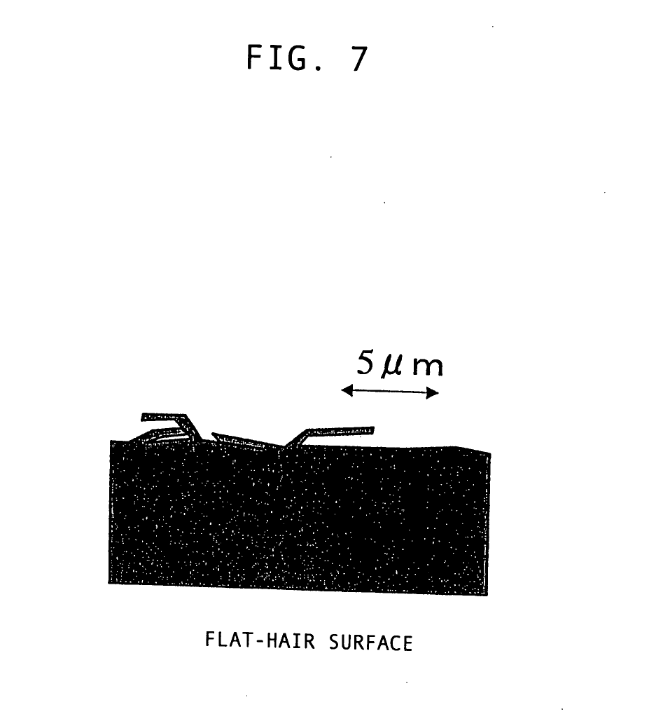

FIG. 7 shows crystals in a flat surface condition. In the condition shown in FIG. 7, the surface of the CNT film 13 is covered with a coating of aluminum in a thickness of about 600 nm.

In some cases, the flat surface is formed by coating the surface of the CNT film 13 with a solid film such as a metal film, etc. In other cases, the flat surface is formed without applying the coating of a solid film to the surface of the CNT film. The flat surface can be formed without the coating of a solid film by, for example, dipping the CNT film into ethanol. Incidentally, the flat surface can also be formed by dipping the CNT film into such liquids as isopropyl alcohol, purified water and hydrochloric acid apart from ethanol. Additionally, there is another approach that involves spraying ethanol on the surface of the CNT film.

There is found a conventional technique similar to this, in which the edge portion of the CNT film is covered with an insulating material. However, with this technique, the insulating material is irradiated with emitted electrons and ions, and charged up. Consequently, paths taken by the respective electrons are curved, and discharge breakdown energy is build up. According to the present invention, such insulating film is not used.

With other conventional techniques, there is a case where a formed CNT film emits more and less electrons in parts. Besides, the electron emission phenomenon described in the scientific literature reporting on electron emission is generally uneven electron emission. Such phenomenon may appear to resemble electron emission controlled by the technique of the present invention. However, the phenomenon described in the scientific literature is an unintentional random event. In the phenomenon, electrons are emitted from a point at a certain time, however, after a period of time, the point which emits electrons disappears, and electrons are emitted from another point. Namely, the phenomenon is uncontrollable and unpredictable.

On the other hand, with the technique of the present invention, electron emission from a specific part can be artificially prevented by, for example, flattening fiber structure by surface tension. In contrast, electron emission from a specific part can be promoted by orienting fiber structure in the part vertically.

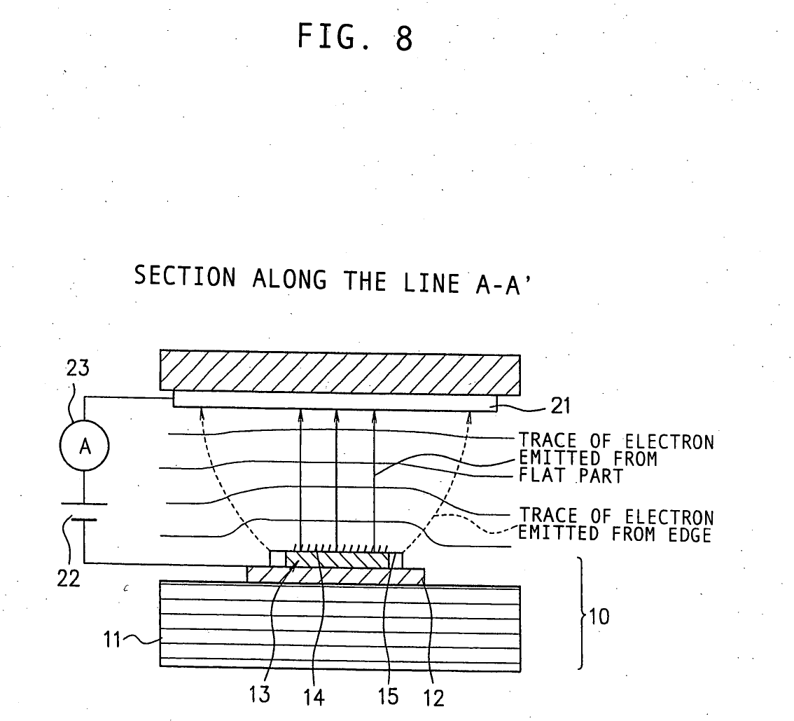

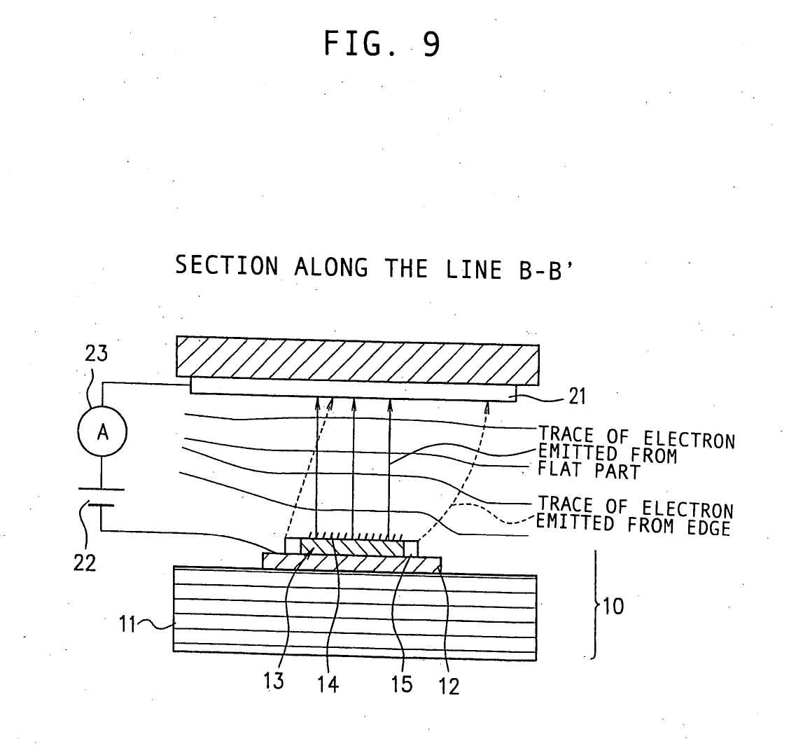

In the following, a description will be made of the situation where a fluorescent material is actually irradiated with electrons using the cathode panel 10 shown in FIG. 5. FIG. 8 is a cross sectional view, taken along the broken line A-A′ of FIG. 5, of a field emission display (FED) using a cathode panel. FIG. 9 is a cross sectional view, taken along the broken line B-B′ of FIG. 5, of the FED.

In FIG. 8, the part indicated as a fluorescent material 21 includes a combination of a fluorescent material and a conducting film. The fluorescent material 21 is connected to the anode of a power supply 22 via an ampere meter 23. Besides, the metal wiring 12 of the cathode panel 10 is connected to the cathode of the power supply 22. The cathode panel 10 and the fluorescent material 21 are held in a vacuum with pressure ranging from 1×10⁻⁴Pa to 1×10⁻⁶Pa.

Electrons emitted from the flat surface of the central portion of the CNT film 13 head straight for the fluorescent material 21 as is shown by electron traces indicated by solid arrows in FIG. 8. As a result, the electrons emitted to the fluorescent material 21 induce excitation light in the material 21. On the other hand, electrons emitted from the edge portion of the film fly in curved paths as shown by dashed arrows in FIG. 8.

However, in the cathode panel according to this embodiment, the surface of the edge portion (periphery) of the CNT film 13 is made flat so as to hardly emit electrons, and therefore, electron emission as shown by dashed arrows in FIG. 8 does not practically occur. Consequently, only the central portion of the CNT film emits electrons.

Incidentally, in the CNT film 13, since electric fields concentrate at the edge of the slender cylindrical structure of each CNT on the nanometer order to the micrometer order in diameter, electrons are emitted in a low electric field. In the flat-hair surface, since the edge of each CNT points downward or sideward, and is tangled with adjacent CNT crystals or hidden under them, electric fields hardly concentrate at the edge. On the other hand, in the raised-hair surface, each CNT is oriented in a direction perpendicular to the surface of the CNT film. Therefore, electric fields concentrate easily.

The FED shown in FIG. 9 is basically similar to that of FIG. 8 except for the shape of the metal wiring 12. In FIG. 9, by the presence of a pad of the metal wiring 12 and a wire to the pad (a curved line connecting the power supply 22 and the metal wiring 12), equipotential surfaces (indicated by horizontal lines in FIG. 9) formed between the fluorescent material 21 and the metal wiring 12 are not symmetrical as can be seen in FIG. 9. Namely, the equipotential surfaces are raised in the right side of FIG. 9, while they are lowered in the left side of FIG. 9.

As to electrons emitted from the edge portion of the film which follow curved paths shown by dashed arrows in FIG. 9 (as described above, electron emission does not practically occur in the edge portion), an electron flies in a path that curves in a direction away from the CNT film 13 in the right side of FIG. 9, while an electron flies in a path that curves in the direction of the center of the CNT film 13 in the left side of FIG. 9.

As set forth hereinabove, in accordance with the first embodiment of the present invention, it is possible to realize the cold cathode that does not emit a curving electron by making the edge portion of the CNT film, being an area from which emitted electrons fly in curved paths, into a flat-hair surface.

[Second Embodiment]

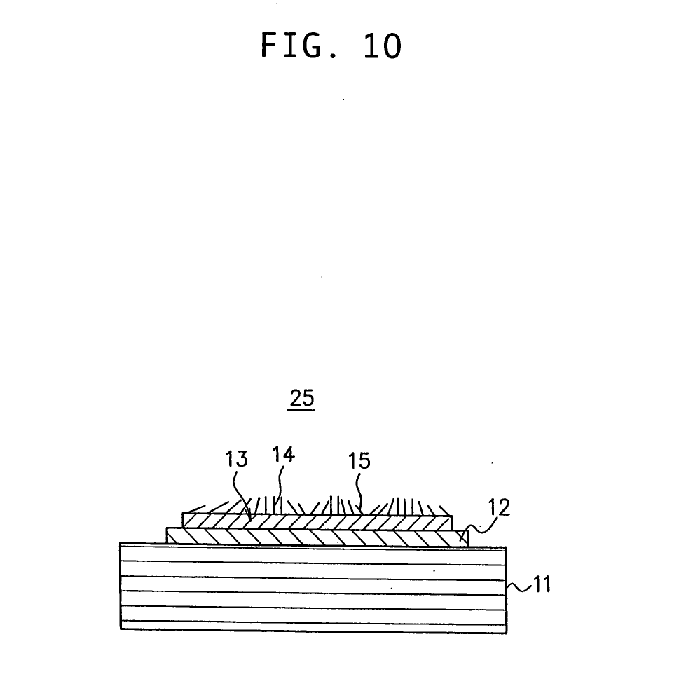

FIG. 10 is, a side view of a cathode panel according to the second embodiment of the present invention. A cathode panel 25 shown in FIG. 10 has the CNT film 13, on which the raised surface portions 14 and the flat surface portions 15 are formed with complete control. In FIG. 10, there are three raised-hair surface portions, and four flat-hair surface portions including edges. Electrons are emitted from the respective raised surface portions 14 with a low voltage. The cathode panel 25 can be provided with a characteristic such that electrons are emitted from a certain portion on the surface of the CNT film 13 (raised-hair surface), while electrons are not emitted from another portion (flat-hair surface). This characteristic can be applied to, for example, character representation.

In the following, a description will be made of character representation using the FED of the aforementioned first embodiment shown in FIG. 8. In FIG. 8, electrons are emitted from only the raised surface portion 14, and induce excitation light in part of the fluorescent material 21 opposite to the raised surface 14. When the cathode panel 25 having a structure as shown in FIG. 10 is located in a position opposite to the fluorescent material 21 as shown in FIG. 8, only part of the material 21 opposite to the raised surface portion 14 emits light.

Next, a method of forming a raised surface and a flat surface according to this embodiment will be explained. First, adhesive tape is attached to the surface of the CNT film, and then it is pulled off to make the entire surface of the CNT film 13 into a raised surface. This effect is similar to the phenomenon such that, when gummed tape is attached on felt cloth and then removed, the surface of the cloth is fluffed up. After that, ethanol is sprayed partly on to the CNT film through a metal plate mask. As a result, the surface wetted with ethanol becomes a flat surface.

Another method of forming a raised surface and a flat surface will be explained. First, the CNT film 13 is dipped into purified water to make its entire surface flat. After that, a sticky paste is applied partly on the surface of the CNT film. The part to which the paste is applied will be made into a raised surface. After the sticky paste is dried/fired, the paste is removed. On this occasion, the part of the surface of the CNT film adheres to the paste and is pulled up. As a result, CNT crystals are raised, thus forming a raised surface.

[Third Embodiment]

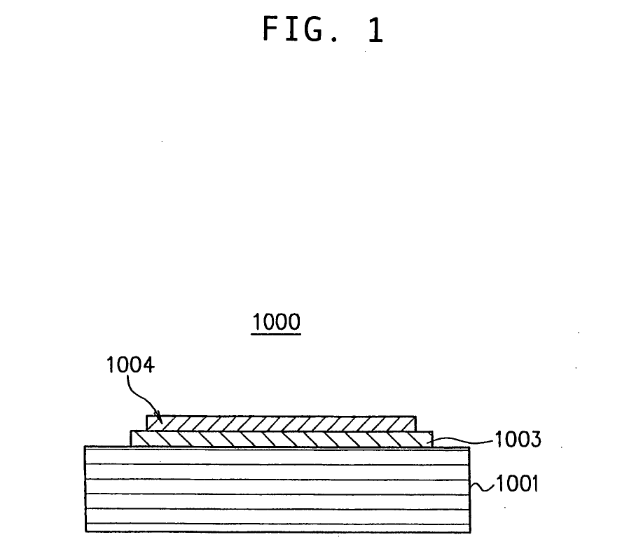

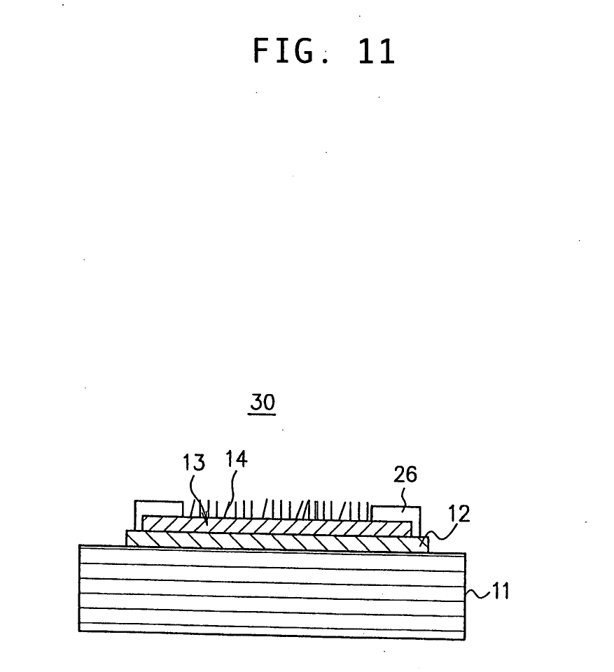

FIG. 11 is a side view of a cathode panel according to the third embodiment of the present invention. A cathode panel 30 shown in FIG. 11 is of essentially the same construction of the conventional cathode panel shown in FIG. 1 as an example. However, the cathode panel of this embodiment is characterized in that the edge portions of the CNT film is covered by a conductive cover 26.

The conductive cover 26 is 600 nm thickness of aluminum. The conductive cover 26 may be a sliver paste film with a thickness of 5 μ. As shown in FIG. 11, the conductive cover 26 also covers the sides of the CNT film 13. In addition, the conductive cover 26 makes contact with the metal wiring 12.

The conductive cover 26 covers the entire edge portions including the sides of the CNT film 13, thus preventing electron emission from the edge portions. Besides, the conductive cover 26 prevents the surface of the CNT film 13 from being charged up. For example, when the CNT film 13 includes an insulator such as a binder, the conductivity of the film 13 is deteriorated. In the case where the surface of such CNT film having a poor conductivity is irradiated by ions and electrons, the surface of the film gets charged up, which may cause difficulty in emitting electrons and a discharge breakdown. The conductive cover 26 reinforces conduction between the surface of the CNT film 13 and the metal wiring 12.

By virtue of the above-described construction according to the third embodiment, CNT crystals on the CNT film 13 in contact with the conductive cover 26 conduct in the sideward direction (in the direction along the surface). Thus, the surface of the film is restrained from being charged up.

[Fourth Embodiment]

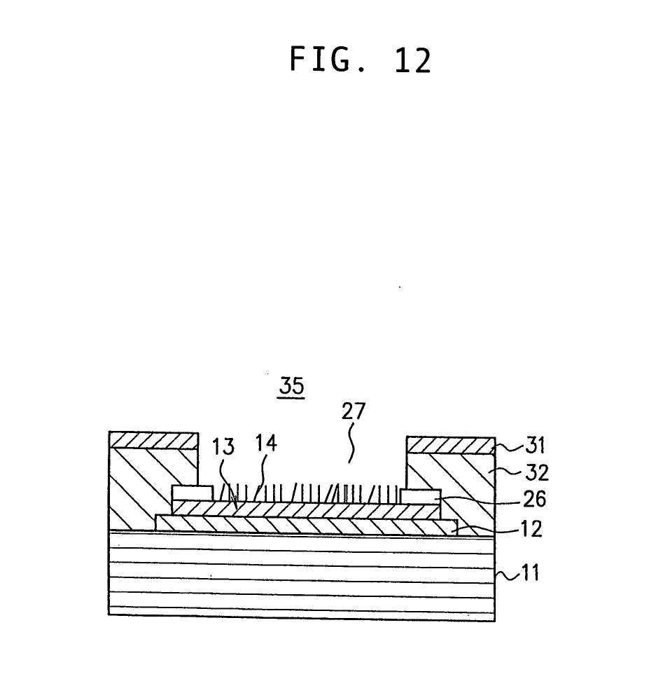

FIG. 12 is a side view of a cathode panel having the normal gate structure according to the fourth embodiment of the present invention. In a cathode panel 35 shown in FIG. 12, the metal wiring 12 is disposed on the glass substrate 11, and the CNT film 13 is deposited thereon. A gate wiring 31 is located above the CNT film 13. The gate wiring 31 is provided with a hole, which will be hereinafter referred to as an emitter hole 27. The surface of the CNT film is exposed at the bottom of the emitter hole portion. The part other than the emitter hole 27 is covered by a gate insulating film 32.

In the cathode panel 35 shown in FIG. 12, the surface of the CNT film is made into the raised surface 14. The vicinity of the edge of the emitter hole 27 is covered by the conductive cover 26. One problem involved in the normal gate structure is that when electrons are emitted from the vicinity of the edge of the emitter hole 27, the electrons jump into the gate insulating film 32, thereby charging up the film 32. Therefore, in accordance with the fourth embodiment of the present invention, the vicinity of the edge of the emitter hole 27 is covered by the conductive cover 26 to restrain electron emission.

In the following, a description will be given of a method of making the surface of the CNT film into a raised surface in an example of the cathode panel according to this embodiment. First, an adhesive sheet is placed on the surface on the gate wiring 31 side of the cathode panel 35, and then the panel 35 is put into a vacuum container. Subsequently, air is evacuated from the vacuum container to a pressure of around 10⁻¹Pa, and the upper side of the adhesive sheet is pressed by a roller to thereby bring the sheet into contact with the surface of the CNT film. Incidentally, the adhesive sheet has a conductive adhesive surface since conductive particles (ultrafine particles of silver) are mixed in its adhesive.

In this condition, conduction between the gate wiring 31 and the metal wiring 12 is checked. When there is conduction between the two, the adhesive sheet makes contact with the surface of the CNT film. However, if there is no continuity between the two, the adhesive sheet is pressed against the surface harder so as to cause conduction. When it is confirmed that there is conduction between the gate wiring 31 and the metal wiring 12 through the adhesive sheet, then it can be confirmed that the adhesive sheet makes contact with the surface of the CNT film. Accordingly, the pressure in the vacuum container is returned to the atmospheric pressure, and the adhesive sheet is removed.

By the aforementioned method, the CNT film is provided with a raised surface. On this occasion, some ultrafine particles of silver remain on the surface of the CNT film. Those particles increase the conductivity of the surface of the CNT film.

[Fifth Embodiment]

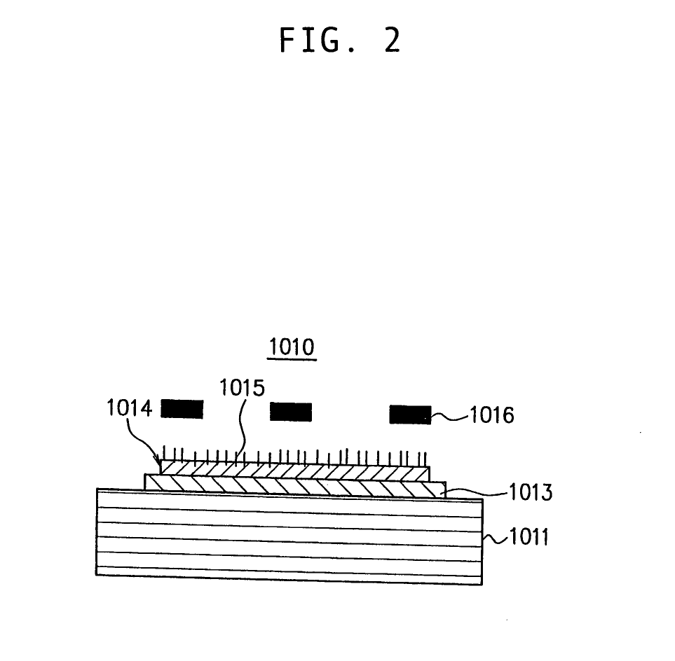

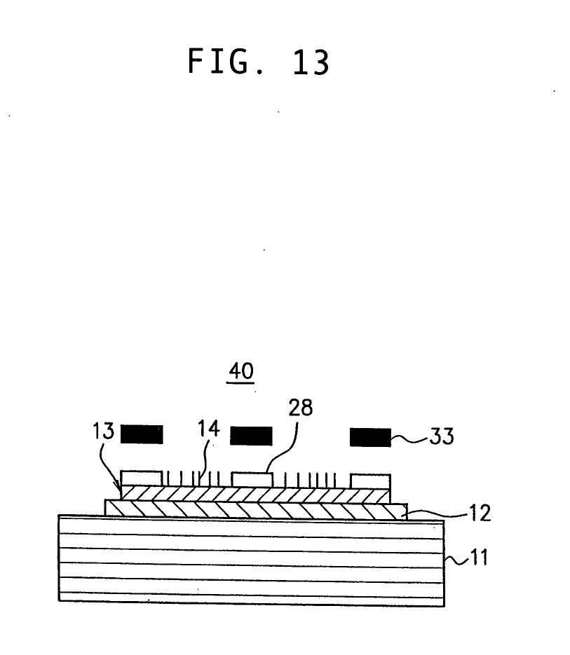

A description will be made of the fifth embodiment of the present invention. FIG. 13 shows a side view of a cathode panel 40 according to the fifth embodiment of the present invention as an example of a cold cathode in which field emission of electrons occurs by grid electrodes. Incidentally, the cathode panel 40 of this embodiment is similar in structure to the conventional panel shown in FIG. 2.

In a cathode panel 40 shown in FIG. 13, portions of the surface of the CNT film 13 just below grid electrode(s) 33 are covered by conductive covers 28. The conductive covers 28 are formed by sputter deposition of nickel metal in a thickness of 100 nm. Besides, portions of the surface of the CNT film 13 corresponding to openings of the grid electrode 33 are raised surfaces.

In the cathode panel having such structure, electron emission from the respective portions of the CNT film 13 below the grid electrode(s) 33 is suppressed. As a result, the percentage of electron emission from the portions corresponding to the openings of the grid electrode 33 increases. By setting up an FED similar in structure to the FED shown in FIG. 8 using this cathode panel to make its fluorescent material emit light, it is possible to selectively irradiate the fluorescent material with electrons. Consequently, the percentage of ineffective electron emission (grid current) running to the grid can be reduced.

[Sixth Embodiment]

A description will be made of the sixth embodiment of the present invention with reference to the cathode panel of the fifth embodiment shown in FIG. 13. In the sixth embodiment, the grid electrode is used as a vapor deposition source when forming the conductive covers.

First, a cathode panel having a structure as shown in FIG. 13 is configured. Then, the cathode panel is put into a vacuum container, and the grid electrode 33 is heated by rendering the electrode 33 conducting. As a result, the grid electrode evaporates, and metal vapors are emitted into the surrounding. The metal is selectively deposited on the surface of the CNT film close to the grid electrode 33. Thereby, the conductive covers 28 are formed on the portions of the surface of the CNT film opposite to the grid electrode(s) 33 as shown in FIG. 13.

The conductive covers can be formed with a grid made of any material by the aforementioned grid evaporation. For example, if the grid electrode is made of tungsten and nickel is attached to the portions of the surface of the grid opposite to the CNT film, nickel, which is a low temperature melting metal, selectively evaporates, while the molybdenum metal being a base metal does not evaporate when heated. Thus, according to this embodiment, it is possible to selectively form self-aligning conductive covers at a low temperature.

[Seventh Embodiment]

A description will be made of the seventh embodiment of the present invention with reference to the cathode panel of the fifth embodiment shown in FIG. 13 as in the case of the sixth embodiment. In the seventh embodiment, the flat surface portions of the CNT film 13 are substituted for the portions illustrated as the conductive covers 28 in FIG. 13. In the following, a method of forming the surface will be explained.

First, the entire surface of the CNT film 13 is left for an hour in an atmosphere of steam at 90% humidity. When the surface temperature of the CNT film is made lower than ambient temperature (ambient temperature: 30° C./the surface temperature of the CNT film: 10° C.), the surface of the CNT film is covered with dew. After that, the CNT film (cathode panel) is put into a drying oven, and dried at 100° C. Consequently, the surface of the CNT film is made flat.

Next, an adhesive is applied to the CNT film from above the grid electrode 33 by spraying or screen printing. The adhesive is hardened or cured, and then pulled off to make portions of the surface of the CNT film 13 corresponding to openings of the grid electrode 33 into a raised surface.

As another method for making the portions corresponding to openings of the grid electrode 33 raised, sandblasting may be used. Copper particles with diameters from 1 μ to 5 μ is used for sandblasting. When bombarded with copper particles from above the grid electrode 33, the surface of the CNT film is roughened on impact. As a result, CNT crystals which have lain flat are raised. That is, the surface becomes a raised surface.

[Eighth Embodiment]

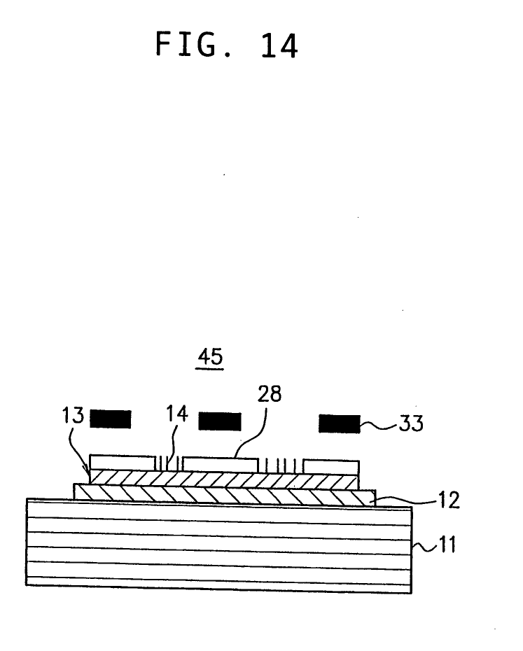

FIG. 14 shows a side view of a cathode panel according to the eighth embodiment of the present invention. The cathode panel 45 shown in FIG. 14 is basically similar in structure to the cathode panel of the aforementioned fifth embodiment shown in FIG. 13 except that the conductive covers 28 are formed on portions of the CNT film 13 opposite the grid electrode(s) 33 and part of the openings.

The cathode panel 45 of this embodiment gives the highest priority on suppressing electrons jumping into the grid electrode 33. In the surface of the CNT film 13, portions, which emit electrons jumping into the grid electrode 33, are covered by the conductive covers 28 to prevent electron emission.

[Ninth Embodiment]

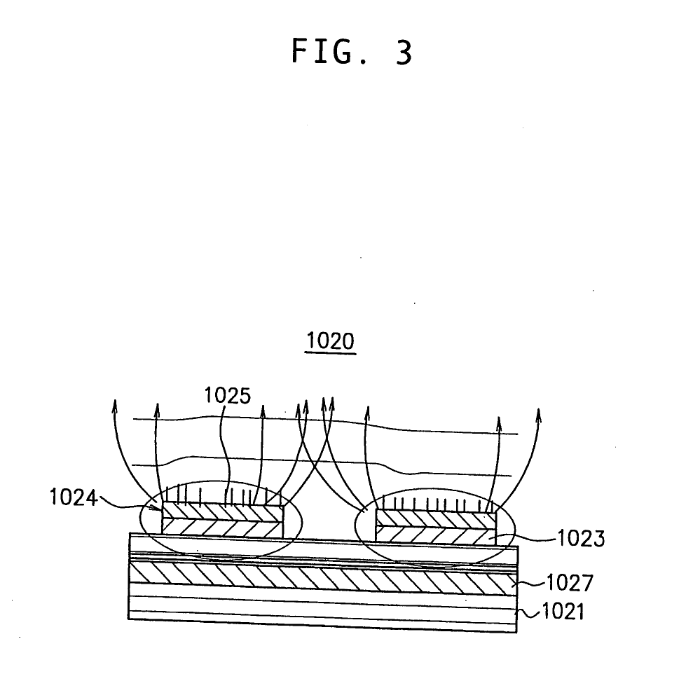

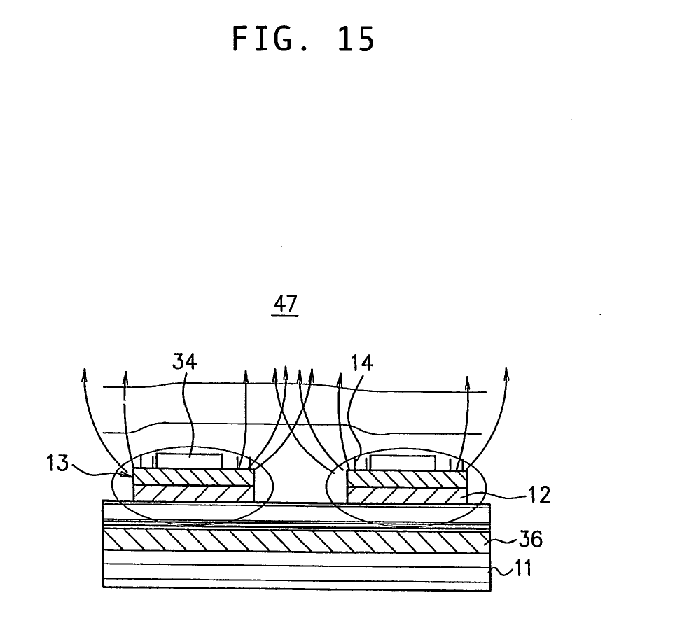

A description will be made of the ninth embodiment of the present invention with reference to FIG. 15. The cathode panel 47 shown in FIG. 15 is an example of a cold cathode called under gate. The cathode panel of this embodiment differs from the conventional cathode panel 102 shown in FIG. 3 in that the central portion of the surface of the CNT film 13 is covered by a conductive cover 34.

With the conventional under gate structure, electrons are emitted form the central portion of the surface of the CNT film by positive voltage applied to the fluorescent material (refer to FIG. 8). Electron emission from the central portion cannot be controlled by the applied voltage of the under gate. If electron emission which cannot be controlled by the under gate takes place, the fluorescent material lights up even when it is undesirable to let the material emit light.

In the cathode panel 47 of this embodiment shown in FIG. 15, the part of the surface of the CNT film 13, where electron emission which cannot be controlled by an under gate 36 occurs, is covered by the conductive cover 34 to solve the above-mentioned problem. Incidentally, as an example of forming a cathode panel which is of similar construction to the cathode panel shown in FIG. 15, the central portion of the CNT film may be made flat instead of being covered by the conductive cover.

[Tenth Embodiment]

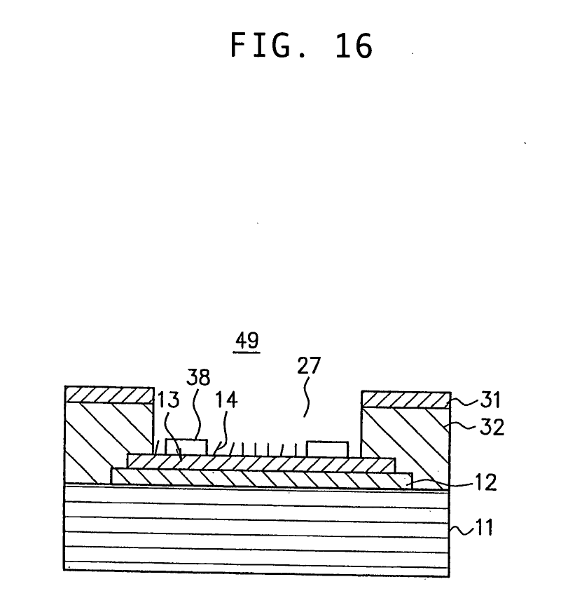

A description will be made of the tenth embodiment of the present invention. FIG. 16 is a side view of a cathode panel 49 according to the tenth embodiment, showing an example of the normal gate structure in which isolated portions emitting no electrons are formed at the bottom of the emitter hole 27. In this embodiment, portions of the exposed surface of the CNT film 13 are covered with conductive covers 38. In the following, the difference between the cathode panel 49 of this embodiment and the cathode panel of the fourth embodiment shown in FIG. 12 will be described.

In the cathode panel shown in FIG. 12, the raised surface is formed inside the part covered by the conductive cover 26. On the other hand, in the cathode panel shown in FIG. 16, the area covered by the conductive cover 38 exists in isolation in the raised surface 14. For example, in the case where electron emission occurs abnormally, part of the surface is repaired to suppress the electron emission, which results in the structure shown in FIG. 16.

When making the surface actually emit electrons, and then depositing conductive films on the part which emits abnormally many electrons by a deposition method such as ink jet or laser CVD, the part may be isolated as is described above.

Apart from repairing, there is a case where the isolated conductive film is formed in the normal manufacturing process. If the emitter hole is shallow, electron emission from the periphery of its bottom can be well controlled by the gate electrode. On the other hand, in the central portion, electron emission cannot be controlled by applied voltage to the gate electrode, and electrons are emitted therefrom by voltage applied to the fluorescent material. For this reason, an FED having a shallow emitter hole may cause trouble that electrons are always emitted regardless of the applied voltage of the gate electrode when applied voltage to the fluorescent material is increased. In order to prevent such trouble, for example, a conductive cover is formed in the central portion of the emitter hole.

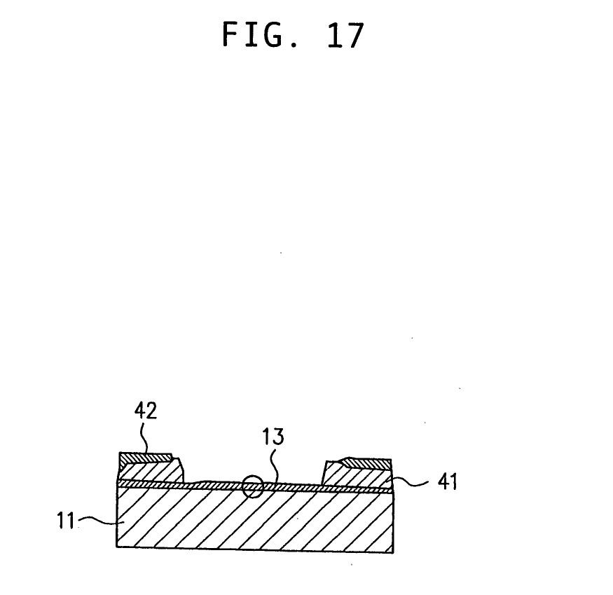

FIG. 17 is a cross sectional view of the emitter hole of a carbon nanotube FED manufactured experimentally. As can be seen in FIG. 17, the carbon nanotube (CNT) film 13 is formed substantially flat at the bottom of the emitter hole. The part of the carbon nanotube film other than the part at the bottom of the emitter hole is covered with an insulating film 41. The opening of a gate wiring 42 is slightly bigger than the opening of the insulating film 41.

Concretely, the insulating film 41 is 20 μm in thickness, and the opening thereof has a diameter of 100 μm. The gate wiring is an aluminum film with a thickness of 200 nm. The opening of the gate wiring is 120 μm in diameter. The openings of the insulating film and gate wiring are shaped as perfect concentric circles.

The applicant also made emitter holes different in size from that of FIG. 17 by way of trial. Insulating films have thicknesses in the range of 2 to 30 μm. The sizes of the openings of the insulating films range from 5 to 200 μm in diameter. The opening of each gate wiring has a diameter equal to or up to 20 μm longer than that of the opening of each insulating film. The applicant tried various combinations of these three conditions. In addition, he made emitter holes each having an oval shape in addition to emitter holes in perfect circler shape to confirm the effect of the present invention.

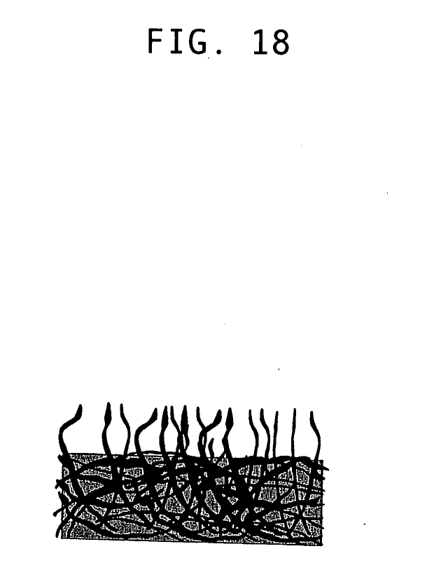

FIG. 18 is an enlarged view of the bottom (the central portion indicated by a circle in FIG. 17) of the emitter hole of the cathode panel according to this embodiment. As shown in FIG. 18, the bottom of the emitter hole has a raised-hair surface. On the other hand, part of the CNT film covered by the insulating film, which is not shown in the drawing, is in a flat-hair surface condition. The insulating film 41 can be made flat because the CNT film beneath the film 41 has a flat surface. In addition, CNT crystals do not project from the insulating film 41, and therefore, the withstand voltage characteristic of the film 41 is improved. Namely, a major characteristic of the structure shown in FIG. 17 is that the CNT film beneath the insulating film 41 has a flat surface.

When forming a CNT film by spray application or the like, the CNT film naturally has a raised surface. That is, CNT crystals project almost vertically from the surface. On the other hand, according to the present invention, the entire surface of the CNT film is wetted by applying purified water in the form of a mist after spray application, and fiber structure is oriented horizontally by the surface tension.

As another example, only a solvent for an organic insulating film is applied first to the surface of the CNT film on the occasion of spin-coating the organic insulating film. Then, before the solvent has evaporated, the organic insulating film is applied onto the CNT film. By this means, fiber structure is oriented horizontally, and an insulating film is deposited thereon. In the part of the surface that forms the bottom of the emitter hole, fiber structure is oriented vertically through contact with an adhesive tape.

[Eleventh Embodiment]

A description will be made of the eleventh embodiment of the present invention. This embodiment is concerned with the electron emission film of a graphite film (not shown). The graphite film does not have minute projections but has exposed potions where a work function is small in places on its surface. That is, the graphite film is a film on which areas where a work function is small are scattered.

The graphite films are deposited in stripes on a glass substrate, and the edge part thereof is covered by nickel metal. As a result, electron emission from the edge part is suppressed, and electrons are emitted from only the central portion of the surface.

[Twelfth Embodiment]

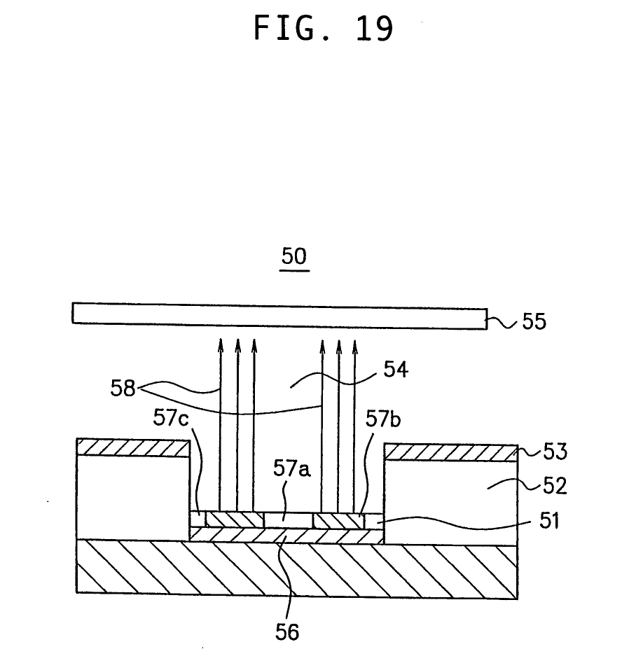

FIG. 19 is a cross sectional view of an FED using carbon nanotubes according to the twelfth embodiment of the present invention. The FED 50 shown in FIG. 19 has a structure in which an optical (fluorescent) screen 55 having a coat of fluorescent material is irradiated with electron beams 58 in a vacuum. A CNT film 51 is deposited on a cathode wiring 56. A gate electrode 53 and an insulating film 52 are cut out to form a cylindrical emitter hole 54. The CNT film 51 is exposed at the bottom of the emitter hole 54. The emitter hole 54 has a diameter of 54 μm with a height of 10 μm.

A centermost area 57a of the CNT film 51, whose center coincides with the center of the film 51, is 3 μm in diameter. CNT crystals each having fine structure on the surface of the film is in a flat-hair condition. The surface of the CNT film in an intermediate area 57b, which is adjacent to the centermost area 57a and has a shape of a doughnut one size larger than the area 57a, is in a raised-hair condition. The doughnut-shaped area has an internal diameter of 3 μm and an external diameter of 8 μm.

An outermost area 57c is adjacent to the intermediate area 57b, and has a shape of a doughnut one size larger than the area 57b. In this area, the surface of the CNT film is in a flat-hair condition. The doughnut-shaped area has an internal diameter of 8 μm and an external diameter of 10 μm. The surface of the outermost area is made flat to suppress electron emission.

With this construction, more electrons are emitted from the intermediate area 57b as compared to the centermost area 57a and outermost area 57c as can be seen in FIG. 19. Consequently, the fluorescent screen 55 is irradiated with the electron beams 58 in a shape of a doughnut.

In a mode of electron beam irradiation, here, a voltage of 6 kV is applied to the fluorescent screen 55 (in a position 2 mm above the gate electrode 53), a voltage of −10V is applied to the cathode wiring 56 and a voltage of +10V is applied to the gate electrode 53. In this condition, the electric field between the cathode wiring 56 and the gate electrode 53 is 2V/μm, and the electric field between the fluorescent screen 55 and the cathode wiring 56 (fluorescent screen electric field) is about 3V/μm.

The FED 50 of this embodiment shuts off the fluorescent screen electric field in the intermediate area 57b and outermost area 57c by the presence of the gate electrode 53. However, the fluorescent screen electric field is applied almost directly to the centermost area 57a. Since high electric field as the fluorescent screen electric field is continuously applied to the centermost area 57a, electrons are easily emitted therefrom. In this embodiment, the surface of the centermost area 57a is made less likely to emit electrons to thereby prevent electron emission which cannot be controlled by the potential at the gate electrode.

In the outermost area 57c, electrons may jump into the insulating film and the gate electrode depending on the surface condition of the CNT film 51. Therefore, the surface of the outermost area 57c is made less likely to emit electrons to suppress the jumping electrons.

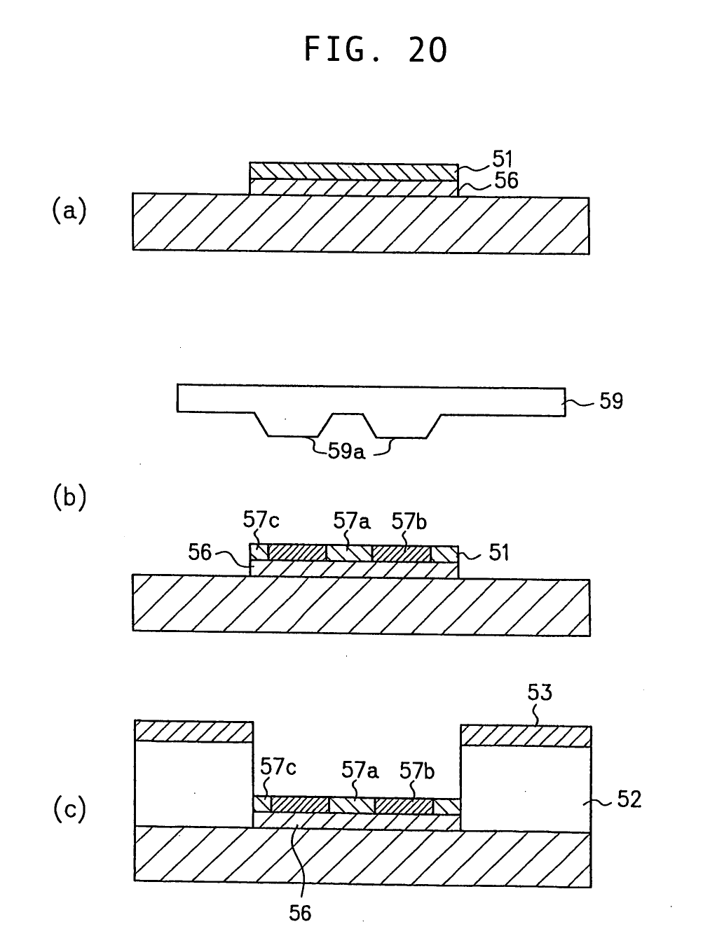

FIG. 20 shows diagrams illustrating the process of manufacturing the cathode panel according to the twelfth embodiment of the present invention. First, at the step shown in FIG. 20(a), the CNT film 51 is deposited on the cathode wiring 56. There are some conceivable methods of deposition. For example, a sheet, which was made beforehand in a different location, may be put on the cathode wiring. In addition, electrodeposition and spraying of CNT particles are also applicable.

Emission does not occur when the CNT film is once dipped into ethanol. At the step shown in FIG. 20(b), an adhesive tape 59 having a convexo-concave surface is pressed against the surface of the CNT film 51. Consequently, the area which is contacted with a convex part 59a of the adhesive tape 59 is to be raised. Incidentally, the convex part of the adhesive tape has a shape of a doughnut. Finally, as can bee seen in FIG. 20(c), the gate insulating film 52 and the gate electrode 53 are formed to thereby form an electron emission apparatus.

[Thirteenth Embodiment]

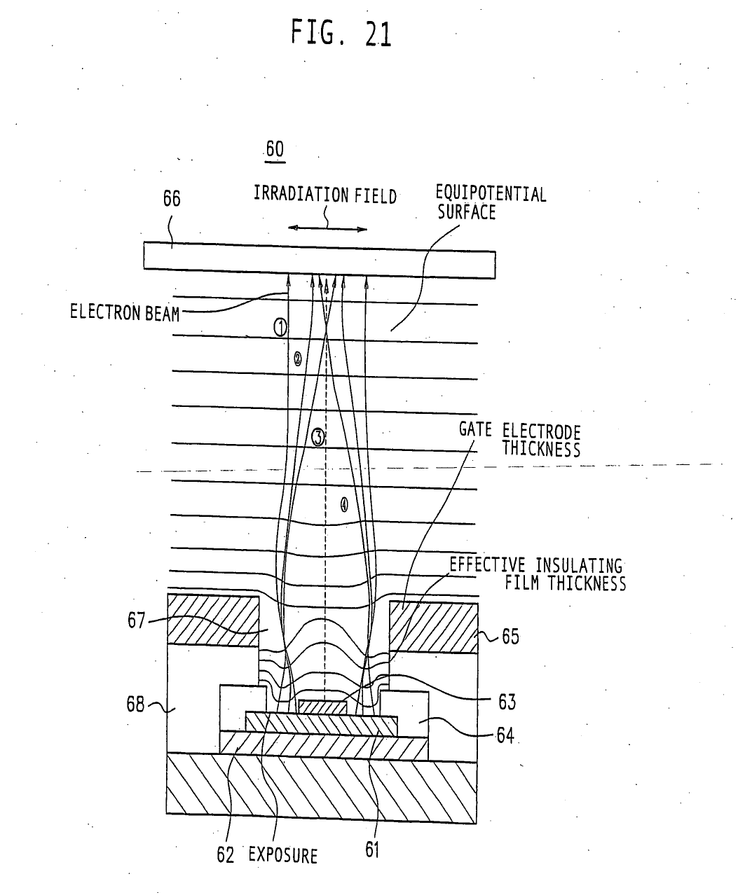

A description will be made of the thirteenth embodiment of the present invention. FIG. 21 is a cross sectional view showing the configuration of an FED using a graphite emission film according to the thirteenth embodiment of the present invention. In the FED 60 of this embodiment, a graphite emission film 61 is deposited on a 1 μm-thick iron wiring 62 formed on a glass substrate by CDV (Chemical Vapor Deposition). The thickness of the formed film is 1 μm thick.

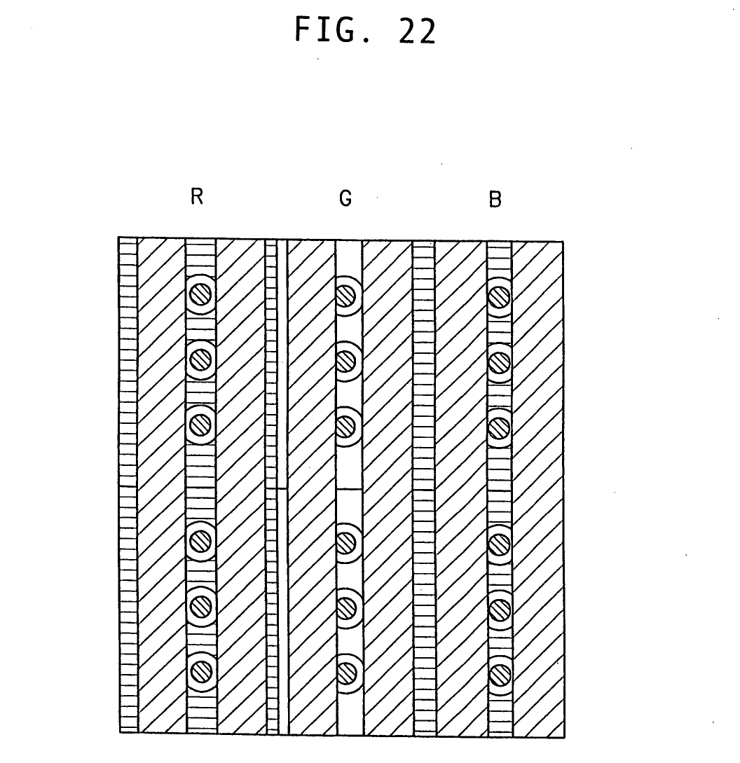

An aluminum center cover 63 is formed on the graphite emission film 61. The aluminum center cover 63 assumes a circular pattern having a diameter of 10 μm. Besides, silver paste surrounding covers 64 are arranged so that the aluminum center cover 63 is placed therebetween. The silver paste surrounding covers 64 assume a stripe pattern as shown in FIG. 22. Each stripe is 50 μm in width. The stripes are oriented in a parallel direction with RGB alignment of the FED 60.

The distance between the silver paste surrounding covers 64 is 30 μm. The aluminum center cover 63 is located in the center of the distance. Incidentally, FIG. 21 shows the FED sectioned across the center of the aluminum center cover 63 in a direction perpendicular to the stripe pattern.

Each exposed portion of the graphite emission film 61 of the FED shown in FIG. 21 is 10 μm in width. In addition, the aluminum center cover 63 has a thickness of 1 μm. On the other hand, the silver paste surrounding covers 64 on the graphite emission film 61 each have a thickness of 5 μm.

In the FED shown in FIG. 21, an insulating film 68 and a gate electrode 65 are formed around the graphite emission film 61 so as to form an emitter hole 67. The effective portion of insulating film corresponding to the emitter hole is 5 μm, and the gate electrode is 8 μm in thickness. The emitter hole 67 has a diameter of 50 μm. The aluminum center cover 63 is located in the center of the emitter hole 67.

The structure in which the gate electrode is thicker than the effective portion of the insulating film (the structure shown in FIG. 21) is called gate electrode thick film stricture. In the gate electrode thick film stricture, the equipotential surface is intricately distorted due to the effect of the placement of the conductive gate electrode as shown in FIG. 21. Electron beams which radiate from the exposed portions of the graphite emission film 61 take paths intricately curved along the distorted equipotential surface to finally reach a fluorescent screen 66.

Incidentally, the equipotential surface is distorted also due to the effect of the presence of the aluminum center cover 63 and the silver paste surrounding covers 64. Particularly, the thick silver paste surrounding covers 64 has a strong effect.

The radiating electron beams in the FED of this embodiment follow paths \mathring{1}, \mathring{2} and \mathring{3} as shown in FIG. 21, respectively. With regard to the path of an electron beam indicated by a broken line \mathring{4}, electrons are not actually emitted from the portion of the emission film covered by the aluminum center cover. However, if it is assumed that the portion is not covered by the aluminum center cover, an electron beam emitted from the center of the emitter hole 67 takes the path \mathring{4}.

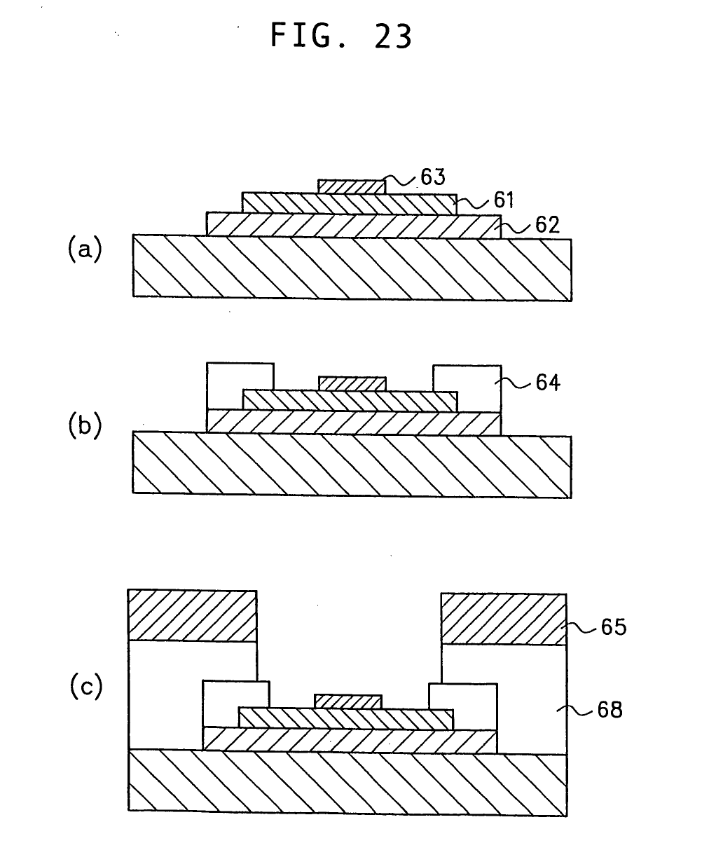

FIG. 23 shows diagrams schematically illustrating the process of forming a cathode panel of the FED shown in FIG. 21. First, aluminum is deposited on the entire surface of the graphite emission film 61 by sputter deposition. Then, an unnecessary portion is etched away using a photolithography technique (FIG. 23(a)). Next, a silver paste is printed in stripes by a screen printing technique (FIG. 23(b)). After that, the insulating film 68 and the gate electrode 65 are formed on the structure shown in FIG. 23(b) by screen printing (FIG. 23(c)).

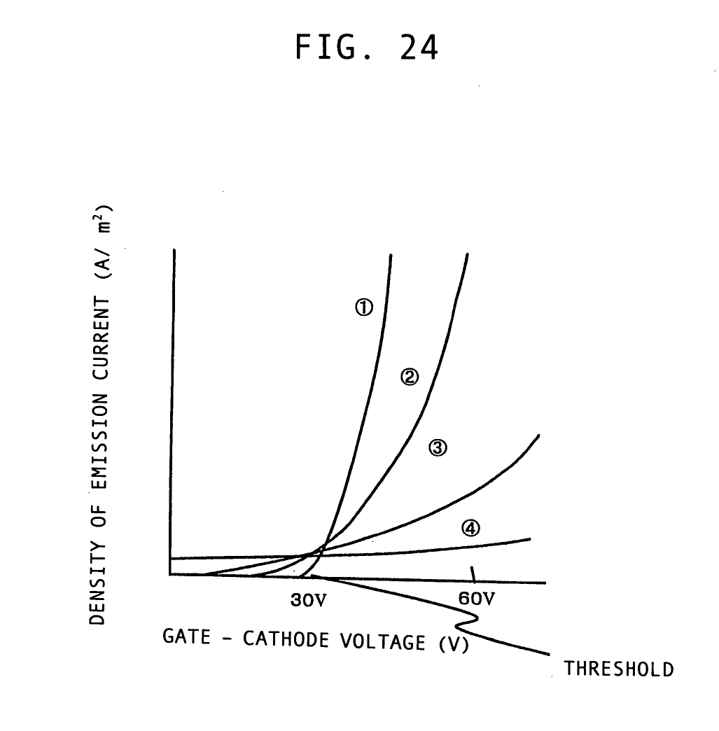

FIG. 24 is a graph showing the emission characteristics of the respective electron beams in the FED shown in FIG. 21, in which gate-cathode voltage is expressed by a horizontal axis and the density of an emission current (unit: ampere/m²) is expressed by a vertical axis. Here, a voltage of 5 kV is applied to the fluorescent screen 66 located in a position 1 mm distant from the gate wiring. In FIG. 24, \mathring{1}, \mathring{2}, \mathring{3} and \mathring{4} indicate positions from which electrons are emitted (refer to FIG. 21). The positions \mathring{1}, \mathring{2}, \mathring{3} and \mathring{4} are 14 μm, 10 μm, 6 μm and 0 μm distant from the center of the emitter hole, respectively.

In comparison of the characteristic of the position \mathring{1} on the periphery of the emitter hole with that of the position \mathring{4} in the center of the hole, with regard to the former, the threshold of voltage is high (30V), and the emission current increases sharply with a voltage equal to or higher than the threshold. The characteristic varies slightly with the positions, from the periphery to the center. With regard to the characteristics of the positions \mathring{2} and \mathring{3}, the thresholds of voltage are 21V and 9V, respectively.

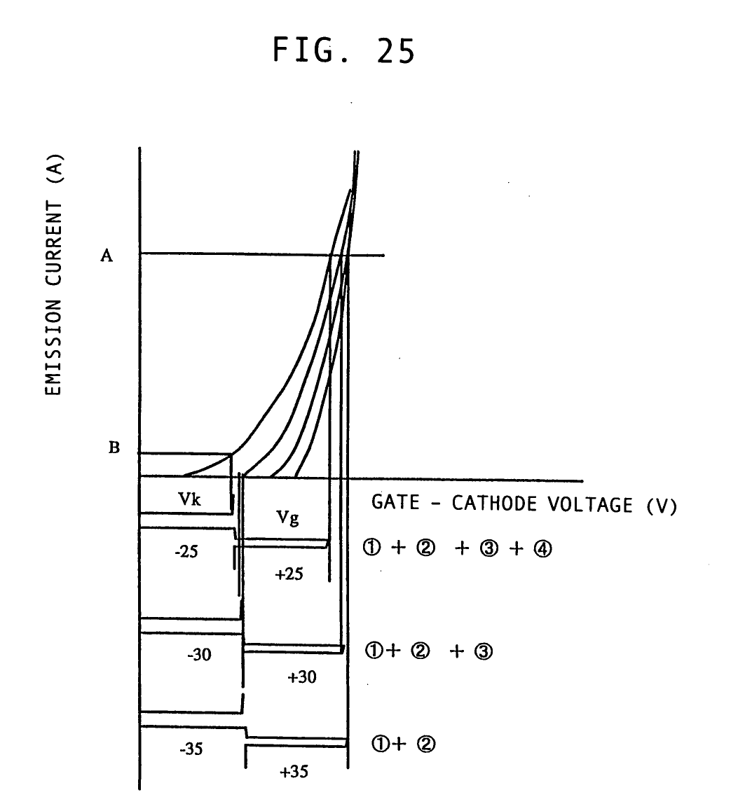

FIG. 25 is a graph showing the sums of actual electron emissions in areas of the above-mentioned positions \mathring{1}, \mathring{2}, \mathring{3} and \mathring{4}. For example, the area \mathring{2} has a shape of a doughnut with an inside radius of 7.5 μm and an outside radius of 12.5 μm. The area \mathring{1} is located outside the area \mathring{2}. That is, a circular boundary between the areas \mathring{1} and \mathring{2} is 12.5 μm distant from the center of the emitter hole. Electron emission \mathring{2} indicates electrons emitted from the area \mathring{2}. Incidentally, electron emission \mathring{4} indicates the amount of electrons emitted from the area \mathring{4} on the assumption that the area \mathring{4} is not covered. In a practical sense, electrons are not emitted from the area \mathring{4} (the covered central area).

As can be seen in FIG. 25, in order to obtain the emission current “A” necessary for the amount of electron emissions from all the areas (\mathring{1}+\mathring{2}+\mathring{3}+\mathring{4}), a gate-cathode voltage of 50V is required. When the gate-cathode voltage (amplitude) is defined to obtain the emission current “A” by pulse-width modulation (PWM), then each voltage is set at 25V (cathode voltage Vk: pulse of −25V (ON) and 0V (OFF)/gate voltage Vg: pulse of 25V (ON) and 0V (OFF)).

However, the emission current “B” in FIG. 25 runs even in OFF state by this setting, and therefore, the fluorescent screen may emit light in OFF state. Additionally, since the central portion of the emission hole is actually covered, a gate-cathode voltage or amplitude of 30V is required for the electron emissions \mathring{1}+\mathring{2}+\mathring{3} as shown in FIG. 25. In this condition, the emission current is shut off in OFF state. FIG. 25 also shows the case of electron emissions \mathring{1}+\mathring{2} for reference.

[Fourteenth Embodiment]

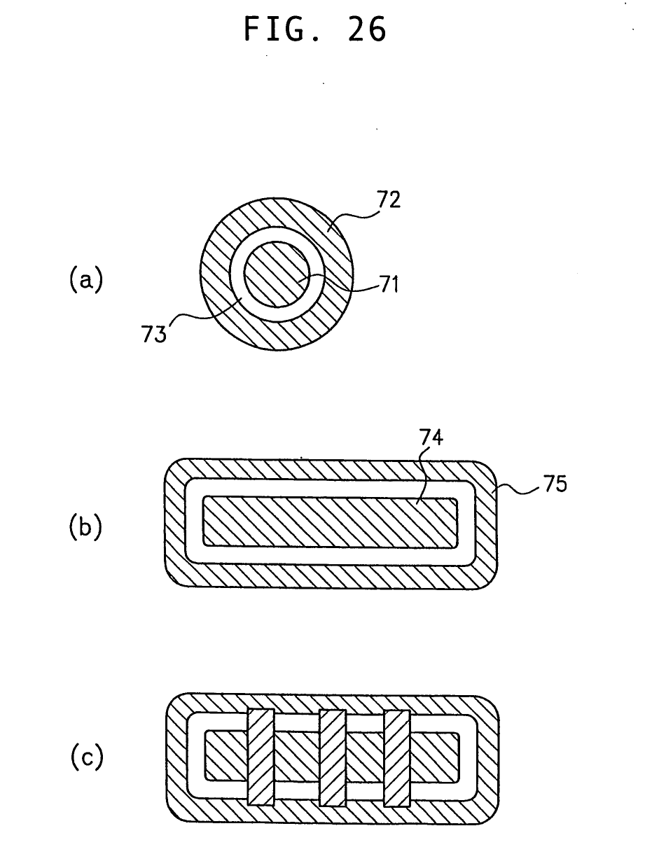

FIG. 26 shows diagrams illustrating a variety of shapes of an electron emitting surface according to the fourteenth embodiment of the present invention. FIG. 26(a) is a diagram showing an example of a doughnut-shaped electron emitting surface. Material with a large work function is placed on the surfaces of a centermost area 71 and an outermost area 72. Meanwhile, material with a small work function is placed on the surface of an intermediate area 73. For example, nickel and barium can be used as the material of a large work function and that of a small work function, respectively.

FIG. 26(b) is a diagram showing an example of an electron emitting surface in substantially a rectangular shape. In FIG. 26(b), areas 74 and 75 are surfaces which hardly emit electrons. FIG. 26(c) is a diagram showing the electron emitting surface of FIG. 26(b) divided into segments. Incidentally, if the electron emitting surface has a great resistance, a material which has a small resistance and is lass likely to emit electrons may be used so that the potential of the entire electron emitting surface is kept constant, and also many electrons are to be emitted.

[Fifteenth Embodiment]

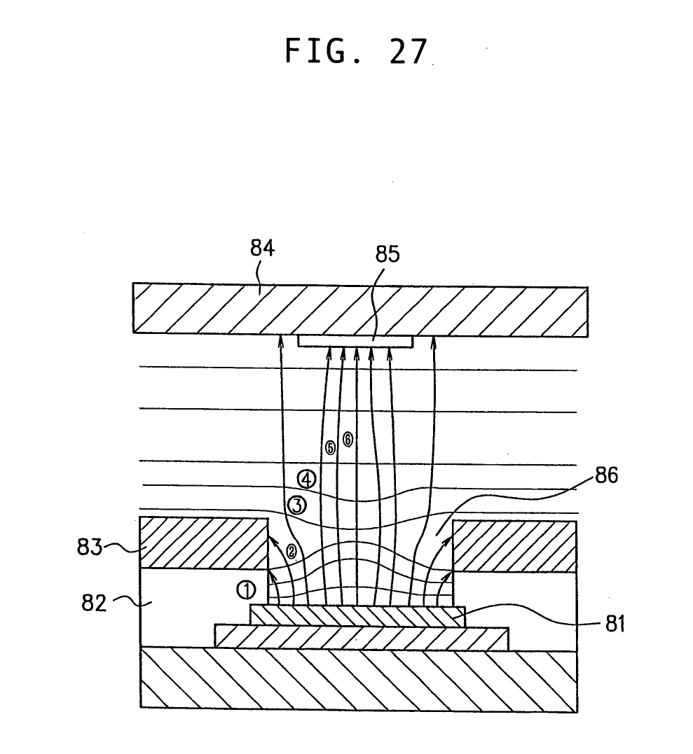

A description will be made of the fifteenth embodiment of the present invention. In the following, a design index to make the periphery of the electron emitting surface emit fewer electrons will be explained. FIG. 27 is a cross sectional view of an FED according to the fifteenth embodiment of the present invention. An electron which is emitted from the periphery of an emission film 81 in FIG. 27 and takes a path \mathring{1} jumps into an insulating film 82, thus causing a discharge breakdown. The electron which takes a path \mathring{2} jumps into a gate electrode 83, and therefore, a gate-cathode current is developed. That is, an impedance drop results in a heavy drive load on the FED. In addition, the gate electrode 83 discharges gas and is charged up due to the electron.

The electron which takes a path \mathring{3} misses a target area 85 and is ineffective. For example, if the color separator area of an RGB color FED (the area called black matrix) is irradiated by electrons, the electrons do not contribute to light emission. Therefore, these electrons are ineffective electrons. The electron which takes the path \mathring{3} is an electron of this kind. On the other hand, electrons which take paths \mathring{4}, \mathring{5} and \mathring{6}, respectively, hit the target area 85. Therefore, the electrons are effective.

It is better that the aforementioned electrons following the paths \mathring{1} to \mathring{3} should not be emitted, and also these are ineffective electrons even if emitted. The electrons taking the paths \mathring{1} to \mathring{3} should be suppressed from the standpoint of optimum design of the FED. With that, according to the present invention, material with a large work function (with a high threshold of voltage necessary for electron emission) is placed on the areas on the emission film, which emit the electrons taking the paths \mathring{1}, \mathring{2} and \mathring{3} to suppress the electron emission from the areas. Alternatively, when using a material, which emits electrons by the effect of electric field concentration at the edges of the minute projections like the CNT, the projections are made flat or chipped off to suppress the electron emission from the areas.

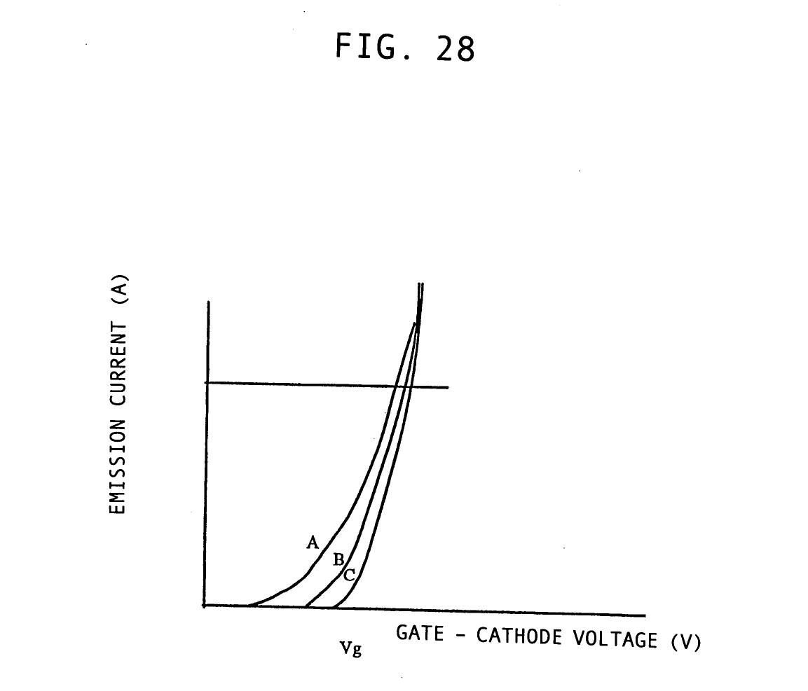

FIG. 28 is a graph showing another design index of an electron emitting surface according to the fifteenth embodiment of the present invention. That is, FIG. 28 shows the characteristic of electron emission in the case where voltage is applied to between the gate-cathode of the FED having a structure shown in FIG. 27. In FIG. 28, “A” designates the emission current characteristic of the paths or electron traces \mathring{4}+\mathring{5}+\mathring{6}. Besides, “B” designates the emission current characteristic of the paths \mathring{4}+\mathring{5}, and “C” designates that of the path \mathring{4} only.

The characteristic “B” can be obtained by suppressing electron emission from the electron emission area \mathring{6} or the central portion of the emission film. The same methods for suppressing electron emission from the areas corresponding to the paths \mathring{1}, etc. can be applied here.

In FIG. 28, with regard to the characteristic “A”, the threshold of voltage is low, and the emission current increases moderately with a voltage equal to or higher than the threshold. This is undesirable since high amplitude is required to drive the FED having the characteristic “A”. Namely, the characteristic “B” or “C” is preferable. However, in comparison with the characteristic “A”, fewer electrons are emitted at the same voltage with the characteristics “B” and “C”. Therefore, the electron emitting surface is designed so as to have areas emitting or not emitting electrons according to the necessary amount of electron emissions and drive amplitude.

While FIG. 28 shows characteristic curves in the case where a relatively low electric field is established between an optical or fluorescent screen 84 and a cathode electrode, emission current flows with the high electric field even if the gate-cathode voltage is 0 (zero). Accordingly, it is important for the design of the FED to prevent electron emission at a voltage of 0V.

To be more precise, in the FED having a shape and a structure as shown in FIG. 27, when an emitter hole 86 is 80 μm in diameter, a gate insulating film (an effective portion of the insulating film 82 exposed in the emitter hole 86) is 20 μm in thickness, the gate electrode 83 is 1 μm in thickness, and the fluorescent screen 84 is located in a position 1 mm distant from the cathode electrode, electron emission form the outermost area of 10 μm width of the emitter hole 86 has to be prevented in order to suppress ineffective electrons which take paths \mathring{1}, \mathring{2} and \mathring{3}, respectively. Besides, electron emission form the centermost area with a radius of 5 μm of the emitter hole 86 should be prevented in order to reduce drive amplitude and suppress electron emission at a voltage of 0V.

[Sixteenth Embodiment]

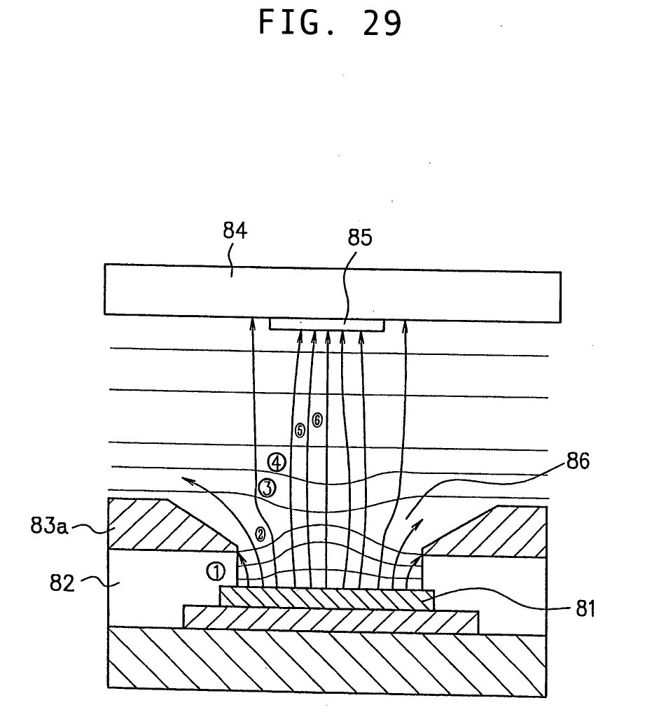

FIG. 29 is a side view showing the configuration of an FED according to the sixteenth embodiment of the present invention. In FIG. 29, those parts corresponding to the components of the FED of the fifteenth embodiment in FIG. 27 are identified with the same numerals. The FED of this embodiment is characterized by the shape of a gate electrode 83a. More specifically, as can be seen in FIG. 29, the gate wiring on the fringe of the gate electrode 83a is tapered in the direction away from the emitter hole 86.

While there are electrons jumping into the gate electrode in the FED of the above-described fifteenth embodiment (refer to FIG. 27), no electron jumps into the gate in this embodiment because of its shape as indicated by a path \mathring{2} in FIG. 29. The electron following the path \mathring{2} is ineffective, however, does not cause the gate electrode to be charged up or to discharge gas.

Incidentally, in the configuration shown in FIG. 29, the electrons which take paths \mathring{1}, \mathring{2} and \mathring{3} are also ineffective electrons. Therefore, an electron emission suppressing treatment (e.g. flattening treatment) should be given to the electron emitting surface to suppress the emission of these electrons. However, even if the treatment has been insufficiently conducted, failure such as a discharge breakdown hardly occurs. Moreover, in the configuration shown in FIG. 29, the effect of a round hole lens caused by the gate electrode 83a (distortion of the equipotential surface) differs from that in the configuration shown in FIG. 27, and the proportion of electrons that hit the target area 85 increases.

While the electron paths or traces in the FED shown in FIG. 29 are denoted by the same numerals as used in FIG. 27 (all the paths \mathring{1}, \mathring{2} and \mathring{3} are for ineffective electrons), there are more ineffective electrons in the FED shown in FIG. 27 as is appreciated from the fact that the equipotential surface of the FED in FIG. 27 is grossly distorted as compared to that of the FED in FIG. 29.

Additionally, in the case where the insulating films and gate wirings (except the taper) of these FEDs have the same thickness, the problems of an electron emission phenomenon at a potential of 0V near center and a slow increase in the amount of emissions are more substantial in the FED shown in FIG. 29. Therefore, a wider area, as compared to the configuration of the FED shown in FIG. 27, near center is covered with aluminum, etc. to suppress electron emission.

[Seventeenth Embodiment]

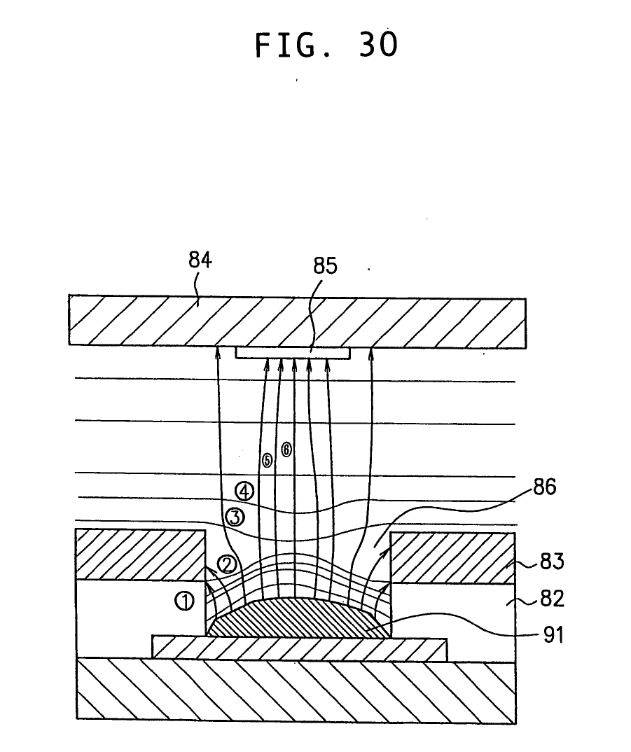

FIG. 30 is a side view showing the configuration of an FED according to the seventeenth embodiment of the present invention. In FIG. 30, those parts corresponding to the components of the FED of the fifteenth embodiment in FIG. 27 are identified with the same numerals. The FED of this embodiment provides an example in which a lump of CNT paste is deposited on a cathode wiring.

As shown in FIG. 30, the FED of this embodiment comprises the gate insulating film 82 of the thickness of 30 μm, the gate wiring 83 of the thickness of 2 μm, the emitter hole with a diameter of 20 μm, and the fluorescent screen 84 arranged at a height of 3 mm. The FED of this embodiment further comprises a CNT paste block 91 that is 15 μm in diameter with a thickness of 15 μm. The CNT paste block 91 is dropped into the emitter hole 86 through a screen printing mask. After that, the CNT paste block 91 is heated to harden or cure part of its binder component, and made into a deposit of frusto-conical shape as shown in FIG. 30.

As can be seen in FIG. 30, the equipotential surface of the FED according to the seventeenth embodiment tends to have a convex distortion due to the slope of the CNT paste block 91 having a frusto-conical shape. Incidentally, In the FED of FIG. 30, voltages of −10V, +10V and 6 kV are applied to the cathode wiring, gate wiring and fluorescent screen 84, respectively. Besides, since the electrons which take paths \mathring{1}, \mathring{2} and \mathring{3}are ineffective, part of the CNT emitting those electrons is made dull in the FED actually manufactured by way of trial.

As to the concrete method of making part of the CNT dull, for example, before being combined with the fluorescent screen 84, the FED is put into a vacuum chamber without the fluorescent screen, and voltage is applied to the gate-cathode of the FED in a pressure in the 10⁻³Pa range to induce emissions. In this case, because of the absence of the fluorescent screen, most of the emitted electrons jump into the insulating film 82 or the gate wiring 83.

Since the degree of vacuum is inappropriate, there are many residual ions, which ionize the vicinity of electron emitting part. Thus, the CNT paste block 91 is irradiated with ions. On this occasion, the slope part of the CNT paste block 91 is selectively damaged by the ions depending on electric fields for the reason that the slope is close to the insulating film 82 and the gate wiring 83. Consequently, the fine structure of the CNT is rounded off.

After going through such trimming process, when the FED is combined with the fluorescent screen and operated as an FED, only the central area of the CNT paste block 91 emits electrons since carbon nanotubes (CNT) in its slope part have been rounded and electric fields hardly converge thereon.

On the other hand, when emissions take place for 1 hour with a current density in the range of 10 to 30 mA/cm² in the condition where the degree of vacuum is inappropriate (10⁻³Pa level), the central portion of the CNT paste block 91 is selectively damaged by the ions, and the CNTs in the part are rounded off. After the second trimming has been finished, air is further evacuated from the vacuum chamber to a pressure of around 10⁻⁵Pa, and then the FED is driven. In this case, the FED operates with no noticeable damage to the CNT paste block 91 since there are few ions. In this stable state, electrons are mainly emitted from the doughnut-shaped area.

[Eighteenth Embodiment]

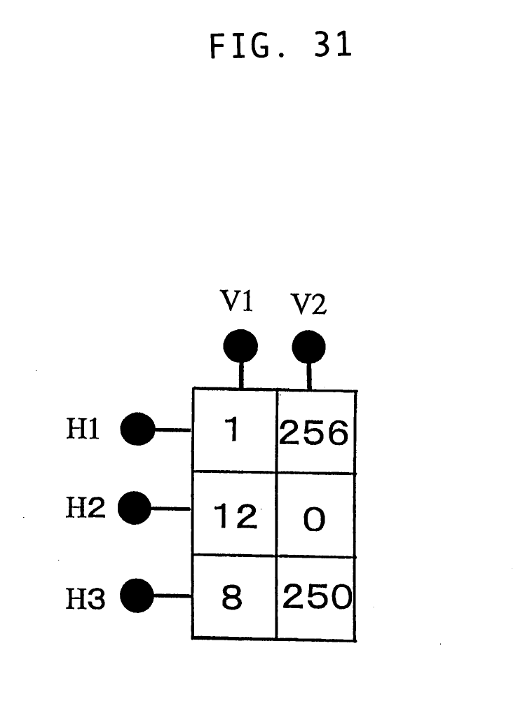

A description will be made of the eighteenth embodiment of the present invention. FIG. 31 is a diagram illustrating the drive of an FED with 2×3 pixels (picture elements) according to the eighteenth embodiment of the present invention. Referring to FIG. 31, a description will be made of operation for making respective pixels illuminate in such a manner that a pixel at the upper left illuminates with an intensity (brightness) of 1, a pixel at the upper right illuminates with an intensity of 256, a pixel at the middle left illuminates with an intensity of 12, a pixel at the middle right illuminates with an intensity of 0 (that is, the pixel does not illuminate), a pixel at the lower left illuminates with an intensity of 8, and a pixel at the lower right illuminates with an intensity of 250. Here, the value “256” is 100% brightness, “128” is 50% brightness, and “1” is 1/256% brightness.

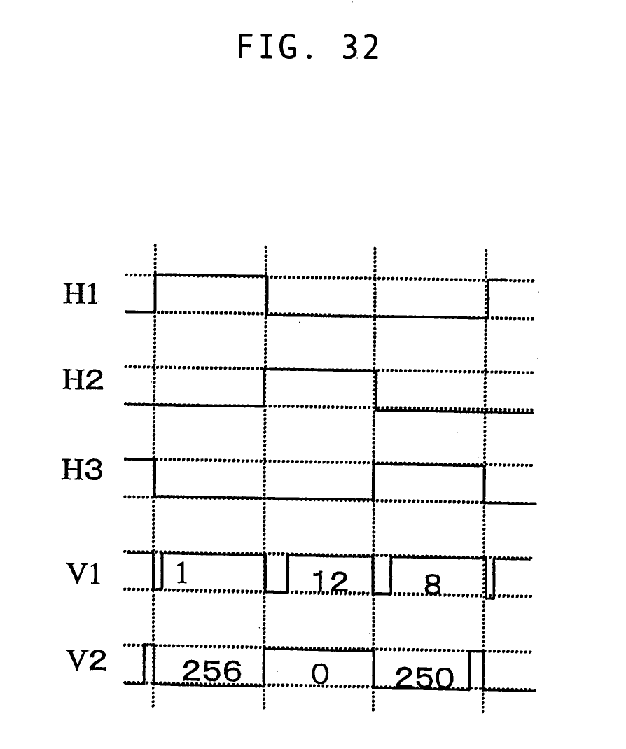

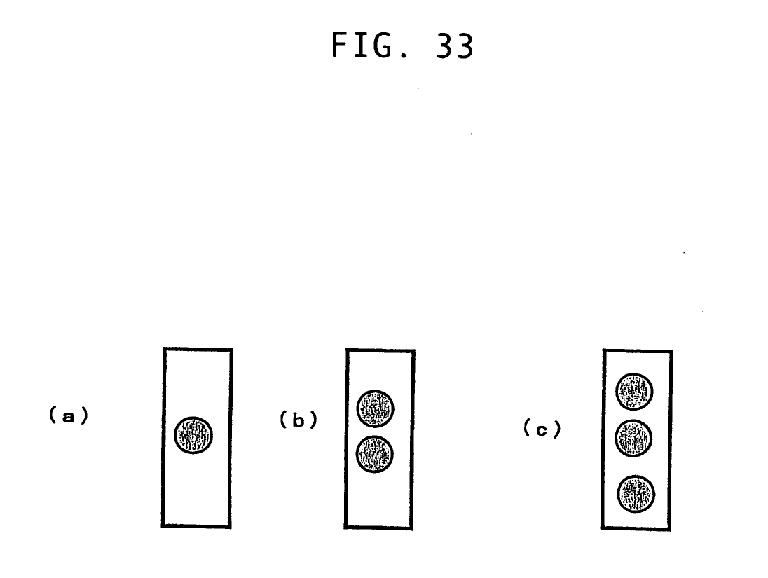

In order to achieve the above-mentioned brightness, the FED is driven by pulse-width modulation (PWM) as shown in FIG. 32. In the following, pixel design for realizing illumination condition in FIG. 31, when H1, H2 and H3 are the same in amplitude and V1 and V2 are of the same amplitude, will be described with reference to FIG. 33, etc.

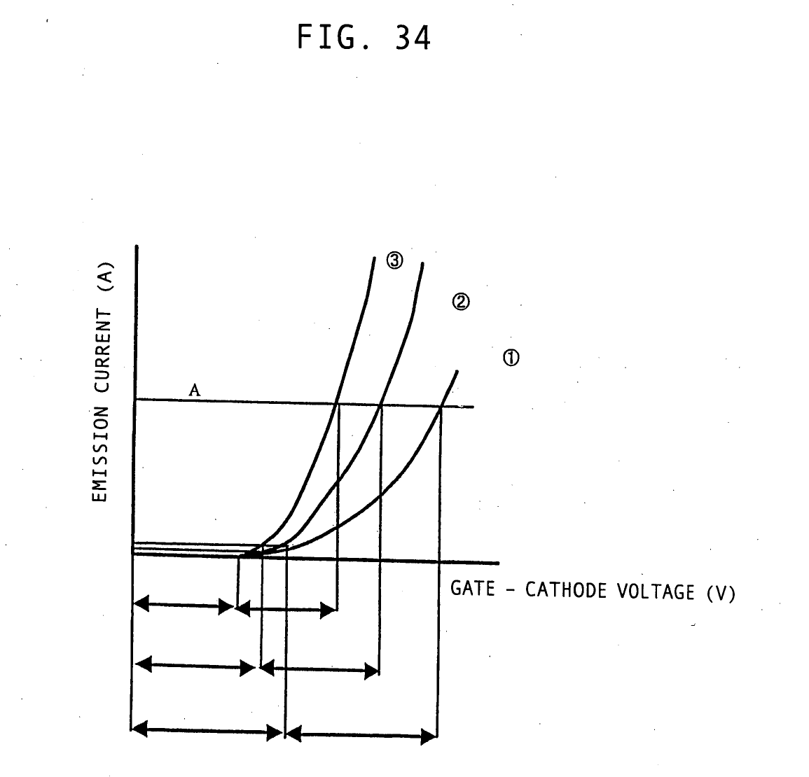

FIGS. 33(a), 33(b) and 33(c) shows one emitter hole, two emitter holes and three emitter holes, respectively. In order to drive the FED with V1 and Hi being of the same amplitude, it is necessary to consider emission characteristics shown in FIG. 34. In FIG. 34, \mathring{1} designates the emission characteristic in the case where the FED is provide with three emitter holes, \mathring{2} designates that in the case where the FED is provide with two emitter holes, and \mathring{3} designates that in the case where the FED is provide with one emitter hole.

Areas indicated by arrows in FIG. 34 represent drive amplitudes when “A” level of electron emission is required to obtain the aforementioned intensity of “256”. More specifically, in the case where there are three emitter holes (\mathring{1}), the FED operates with the lowest amplitude. The drive amplitude increases in the case of two emitter holes (\mathring{2}), and further increases in the case of one emitter hole (\mathring{3}).

Incidentally, in the cases of \mathring{2} and \mathring{3}, electrons are emitted even with a OFF level of drive voltage, and desired brightness (colors) may not be achieved.

### Industrial Applicability

As set forth hereinabove, according to the present invention, a continuous electron emission film serves as an electron source and is composed of at least two areas, wherein an electric field necessary for the emission of a certain amount of electrons on the surface of one of the areas is different from that on the surface(s) of the other area(s), the work function of the material surface, which emits electrons, of one of the areas is different from that of the other area(s), regarding irregularities on the surfaces of the areas, the average radius of the edges of convexities in one of the areas is different from that in the other area(s), the amount of emitted electrons per unit area in one of the areas is different from that in the other area(s), and/or regarding irregularities on the surfaces of the areas, the density of convexities per unit area in one of the areas is different from that in the other area(s). Thus, in an electric field electron emission device using the electron emission film, a micropattem can be defined on the surface of the electron emission film regardless of the micro-fabrication limit of the film itself, and it becomes possible to change the electron emission characteristic of the film.

Besides, in accordance with the present invention, a continuous electron emission film serves as an electron source and includes an innermost area, an intermediate area and an outermost area, wherein the electron emission characteristics of the innermost area and outermost area are different from that of the intermediate area. Thus, in an electric field electron emission device using the electron emission film, electron emission can be controlled with a micropattern independent of the micro-fabrication limit of the electron emission film.

With the use of the electron emission film according to the present invention, it is possible to provide a highly reliable electron emission device which is capable of displaying characters or letters and the like easily by light emitting, and in which an abnormal discharge hardly occurs.

1-23 (canceled).

24. A continuous electron emission film, which serves as an electron source and includes at least two areas, wherein, regarding irregularities on the surfaces of the areas, the average radius of the edges of convexities in one of the areas is different from that in the other area.

25. A continuous electron emission film, which serves as an electron source and includes at least two areas, wherein, regarding irregularities on the surfaces of the areas, the density of convexities per unit area in one of the areas is different from that in the other area.

26. The electron emission film claimed in claim 24, wherein an electric field necessary for the emission of a certain amount of electrons on the surface of one of the areas is different from that on the surface of the other area.

27. The electron emission film claimed in claim 25, wherein an electric field necessary for the emission of a certain amount of electrons on the surface of one of the areas is different from that on the surface of the other area.

28. The electron emission film claimed in claim 24, wherein the work function of the material surface, which emits electrons, of one of the areas is different from that of the other area.

29. The electron emission film claimed in claim 25, wherein the work function of the material surface, which emits electrons, of one of the areas is different from that of the other area.

30. The electron emission film claimed in claim 24, wherein the amount of emitted electrons per unit area in one of the areas is different from that in the other area.

31. The electron emission film claimed in claim 25, wherein the amount of emitted electrons per unit area in one of the areas is different from that in the other area.

32. A continuous electron emission film, which serves as an electron source and includes at least two areas, wherein, in one of the areas:
an electric field necessary for emitting electrons is large;
the work function of a material surface which emits electrons is large;
regarding irregularities on the surface of the area, the average radius of the edges of convexities is large;
the density of convexities per unit area is low; and/or
the amount of emitted electrons per unit area is small as compared to the adjacent area.

33. A continuous electron emission film, which serves as an electron source and includes at least two areas, wherein one of the areas is located in at least part of the periphery of the electron emission film, and in the area:
an electric field necessary for emitting electrons is large;
the work function of a material surface which emits electrons is large;
regarding irregularities on the surface of the area, the average radius of the edges of convexities is large;
the density of convexities per unit area is low; and/or
the amount of emitted electrons per unit area is small as compared to the adjacent area.

34. A continuous electron emission film, which serves as an electron source and includes at least two areas, wherein one of the areas is located in at least part of the central portion of the electron emission film or located so as not to include the periphery of the film, and in the area:
an electric field necessary for emitting electrons is large;
the work function of a material surface which emits electrons is large;
regarding irregularities on the surface of the area, the average radius of the edges of convexities is large;
the density of convexities per unit area is low; and/or
the amount of emitted electrons per unit area is small as compared to the adjacent area.

35. A continuous electron emission film, which serves as an electron source and includes an innermost area, an intermediate area and an outermost area, wherein the electron emission characteristics of the innermost area and outermost area is different from that of the intermediate area.

36. A continuous electron emission film, which serves as an electron source and includes at least three areas, wherein one of the areas is located in at least part of the periphery of the electron emission film or at least part of the central portion thereof so as not to include the periphery of the film, and in the area:
an electric field necessary for emitting electrons is large;
the work function of a material surface which emits electrons is large;
regarding irregularities on the surface of the area, the average radius of the edges of convexities is large;
the density of convexities per unit area is low; and/or
the amount of emitted electrons per unit area is small as compared to the adjacent area.

37. A continuous electron emission film provided with fiber structure, which serves as an electron source and includes at least two areas, wherein the rate at which fibers are oriented in a direction perpendicular to the film in one of the areas is different from that in the other area.

38. A continuous electron emission film provided with fiber structure, which serves as an electron source and includes at least two areas, wherein the rate at which fibers are oriented in a direction parallel to the film in one of the areas is different from that in the other area.

39. A continuous electron emission film provided with fiber structure, which serves as an electron source and includes at least two areas, wherein the proportion of fibers, which form the fiber structure, having diameters smaller than a predetermined diameter varies according to the areas.

40. A continuous electron emission film provided with fiber structure, which serves as an electron source and includes an innermost area, an intermediate area and an outermost area, wherein the rate at which fibers are oriented in a direction parallel to the film in the innermost and outermost areas is higher than that in the intermediate area.

41. A continuous electron emission film provided with fiber structure, which serves as an electron source and includes at least two areas, wherein one of the areas is covered with a conductive film, and the conductivity of the conductive film is larger than that of the other area.

42. The electron emission film claimed in claim 35, characterized in that the innermost area, the intermediate area and the outermost area are arranged concentrically.

43. The electron emission film claimed in claim 40, characterized in that the innermost area, the intermediate area and the outermost area are arranged concentrically.

44. The electron emission film claimed in claim 35, characterized in that the innermost area, the intermediate area and the outermost area are rectangular areas having the same center.

45. The electron emission film claimed in claim 40, characterized in that the innermost area, the intermediate area and the outermost area are rectangular areas having the same center.

46. An electric field electron emission device provided with the electron emission film claimed in one of claim 24, wherein the electron emission film is arranged so that part of the surface of the prescribed area or the side of the film is contacted with an insulating film.

47. An electric field electron emission device provided with the electron emission film claimed in claim 24, wherein the electron emission film is arranged so that part of the surface or the side of the first area including part of the periphery of the film, the second area not including part of the central portion or the periphery of the film or the third area including part of the periphery of the film and not including part of the central portion or the periphery of the film is contacted with an insulating film.

48. The electric field electron emission device claimed in claim 46, characterized in that the side or edge part of the electron emission film is covered by a conductive film.

49. The electric field electron emission device claimed in claim 46, characterized in that a gate electrode is disposed on part of the upper surface of the insulating film.

50. The electric field electron emission device claimed in claim 49, characterized in that the edge of the gate electrode corresponding to a hole made therein is tapered in an upward direction.

51. The electric field electron emission device claimed in claim 46, characterized in that the electron emission film is a deposit of carbon nanotubes (CNT) in substantially a frusto-conical shape.
